(19) United States
(12) Patent Application Publication
(10) Pub. No.: US 2026/0357386 A1
(43) Pub. Date: Nov. 12, 2026

(54) CR-ZR-N ALLOY MATERIAL AND ALLOY COATING, ALLOY FILM PRODUCT, USE IN HIGH-BRIGHTNESS SURFACE COATING, AND PREPARATION METHOD

(71) Applicant: VITALINK INDUSTRY (SHENZHEN) CO., LTD., Shenzhen, Guangdong (CN)

(72) Inventors: Yue DONG, Shenzhen (CN); Zhi TAN, Shenzhen (CN); Jiamin LIANG, Shenzhen (CN); Feng HUANG, Shenzhen (CN); Wei WANG, Shenzhen (CN)

(21) Appl. No.: 19/477,015

(22) PCT Filed: Feb. 1, 2024
(86) PCT No.: PCT/CN2024/075166

§ 371 Date: Oct. 20, 2025

(30) Foreign Application Priority Data
Jun. 21, 2023 (CN) 202310749467.5

(51) Int. Cl. C22C 27/06; C23C 14/16; C23C 14/34; C23C 14/54

(52) U.S. Cl. CPC C22C 27/06; C23C 14/16; C23C 14/3414; C23C 14/542

(57) ABSTRACT

The present application relates to a Cr—Zr—N alloy material and alloy coating, an alloy film product, the use in a high-brightness surface coating, and a preparation method. The chemical formula of the Cr—Zr—N alloy material is (CrₓZr_{y}N_{z})Mₐ, wherein M is a doping element, x, y, z and a are each independently atomic ratios, 47.1≤x≤81.6, 12.1≤y≤33.2, 4.7≤z≤35.9, and 0≤a/(x+y+z+a)≤0.05.

### RELATED APPLICATIONS

This application is an U.S. national phase application under 35 U.S.C. § 371 based upon international patent application No. PCT/CN2024/075166 filed on Feb. 1, 2024, which itself claims priority to Chinese patent application No. 202310749467.5, filed on Jun. 21, 2023, entitled “CR-ZR-N ALLOY MATERIAL AND ALLOY COATING, ALLOY FILM PRODUCT, USE IN HIGH-BRIGHTNESS SURFACE COATING, AND PREPARATION METHOD”. The contents of the above identified applications are hereby incorporated by reference in their entireties.

### TECHNICAL FIELD

The present application relates to the field of alloy coating technology, and in particular to a Cr—Zr—N alloy material and an alloy coating, an alloy film product, an application in a high-brightness surface coating and a preparation method.

### BACKGROUND

With the development of science and technology and the improvement of quality of life, people are not only concerned about the practical performance of products in various fields such as automobiles, wearable products, 3C products and sport products, but also gradually put forward higher requirements on the appearance of products. For example, the attention paid to the high brightness of the product surface has greatly increased. In these products, the representative “3C products” are a general term for computer, communication, and consumer electronic products, also known as “information appliances”, such as computers, tablets, mobile phones, or digital audio players. Since 3C products generally have small sizes, they are often collectively referred to as “3C small appliances”.

One of methods to improve the surface brightness of conventional products is to use an alloy coating with a high chromium (Cr) content. However, this type of coating usually exhibits weak corrosion resistance and is prone to corrosion during use.

Therefore, it is necessary to develop novel alloy coating materials to prepare alloy coatings with high brightness and good corrosion resistance.

### SUMMARY

According to various embodiments and examples of the present application, one aspect of the present application provides a Cr—Zr—N alloy material. In addition, other aspects of the present application also provide a Cr—Zr—N alloy coating and an alloy film product, an application of the Cr—Zr—N alloy material or Cr—Zr—N alloy coating in a high-brightness surface coating, and a method for preparing the Cr—Zr—N alloy coating.

In a first aspect of the present application, a Cr—Zr—N alloy material is provided. The Cr—Zr—N alloy material is represented by a chemical formula of (CrₓZr_{y}N_{z}l)Mₐ, where M is a doping element, wherein x, y, z, and a are each independently atomic ratios, 47.1≤x≤81.5, 12.1≤y≤33.2, 4.7≤z≤35.9,and 0≤a/(x+y+z+a)≤0.05.

In some embodiments, a sum of x, y, and z is 100.

In some embodiments, y is greater than z.

In some embodiments, 63.19−0.925y≤x≤95.79−y, and 31.4+0.9y≤x≤18.5y−171.85.

In some embodiments, the doping element is a non-metallic element, a metallic element, or a combination thereof.

The non-metallic element includes one or more selected from O, C, B, Si, and Ar.

The metallic element includes one or more of Ti, V, Nb, Mo, Hf, Ta, W, Ni, Mo, Fe, Ag, Au, Cu, and Al.

In some embodiments, 0≤a/(x+y+z+a)≤0.02.

In a second aspect of the present application, a Cr—Zr—N alloy coating is provided. The Cr—Zr—N alloy coating includes a film layer formed with the Cr—Zr—N alloy material in the first aspect of the present application.

In some embodiments, the Cr—Zr—N alloy coating satisfies the following two characteristics:
in an X-ray diffraction (XRD) pattern of the Cr—Zr—N alloy material or the Cr—Zr—N alloy coating, there is a peak in a diffraction angle 2θ (°) range of 30° to 50°, and at least one 2θ (°) diffraction peak in the range of 30° to 50° has a full width at half maximum (FWHM) of ≥2°; and
in a radial intensity profile corresponding to a selected area electron diffraction (SAED) pattern of the Cr—Zr—N alloy material or the Cr—Zr—N alloy coating, with a characteristic interatomic spacing as a horizontal axis, and a diffraction intensity as a vertical axis, there is a diffraction peak in a range of 2.0 Å to 3.0 Å, and at least one diffraction peak in the range of 2.0 Å to 3.0 Å has an FWHM of ≥0.21 Å.

In some embodiments, the Cr—Zr—N alloy coating satisfies one or more of the following characteristics:
the X-ray diffraction pattern of the Cr—Zr—N alloy coating is obtained by Cu target Kα radiation; and
the selected area electron diffraction pattern of the Cr—Zr—N alloy coating is obtained by using a transmission electron microscope, with an electron acceleration voltage of 200 kV, and a selected area diaphragm diameter of 900 nm.

In some embodiments, the Cr—Zr—N alloy coating has a thickness of dₘᵢₙ to 6 μm, wherein dₘᵢₙ is selected from 10 nm to 50 nm.

Optionally, dₘᵢₙ is 10 nm, 20 nm, 25 nm, 30 nm, 40 nm or 50 nm.

Optionally, a thickness of the Cr—Zr—N alloy coating is 1 μm to 2.5 μm.

In a third aspect of the present application, an alloy film product is provided. The alloy film product includes a substrate and the Cr—Zr—N alloy coating in the second aspect of the present application. The Cr—Zr—N alloy coating is disposed on at least one side of the substrate.

In some embodiments, a surface material of the substrate is one of an alloy, an elemental metal, or a non-metallic inorganic material.

Optionally, the alloy includes one or more material types selected from nickel-based, iron-based, tungsten-based, titanium-based, silicon-based, aluminum-based, copper-based, cobalt-based, zirconium-based, and zinc-based materials.

Optionally, the elemental metal is any one of zinc, gold, platinum, zirconium, hafnium, niobium, tantalum, nickel, copper, aluminum, iron, silver, and chromium.

Optionally, the non-metallic inorganic material includes one or both of ceramics and glass.

In some embodiments, the surface material of the substrate is one of light alloys or one of stainless steels.

Optionally, the light alloy includes one or more of a titanium alloy, an aluminum alloy, and a magnesium alloy.

In some embodiments, the alloy film product satisfies one or more of the following characteristics:
the Cr—Zr—N alloy coating and the substrate are in direct contact with each other, or a transition layer is provided between the alloy coating and the substrate; and
the Cr—Zr—N alloy coating is disposed on a surface of the alloy film product; or a surface layer is provided on one side of the Cr—Zr—N alloy coating away from the substrate and the surface layer is a single-layer structure or a multi-layer structure.

In some embodiments, the alloy film product is one of a 3C digital product, an automotive product, an aerospace product, a wearable product, and a sport product.

In a fourth aspect of the present application, there is provided an application of the Cr—Zr—N alloy material in the first aspect of the present application in preparing a high-brightness surface coating or an application of the Cr—Zr—N alloy coating in the second aspect of the present application as a high-brightness surface coating. The high-brightness surface coating has a brightness value L of ≥70 as determined by Lab method. The high-brightness surface coating is also a corrosion-resistant protective coating.

In a fifth aspect of the present application, a method for preparing an alloy coating is provided. The method includes the following step: depositing constituent elements of the Cr—Zr—N alloy coating in a predetermined atomic ratio on at least a portion of a surface of a substrate through vapor deposition technique to form the Cr—Zr—N alloy coating as described in the second aspect of the present application.

In some embodiments, the method for preparing the Cr—Zr—N alloy coating includes the following step: sputter deposition of constituent elements of the Cr—Zr—N alloy coating on at least a portion of the surface of the substrate by using one or more target materials including chromium and zirconium under introducing a mixed gas including argon gas and nitrogen-containing gas to form the Cr—Zr—N alloy coating.

In some embodiments, the preparation method satisfies one or more of the following characteristics:
the sputter deposition is performed at a temperature of 30 °C to 330 °C;
the mixed gas including argon gas and nitrogen-containing gas has a total gas pressure of 0.3 Pa to 1.2 Pa;
the target materials include a chromium target and a zirconium target, a power density of the chromium target is 3.5 W/cm² to 6.7 W/cm², and a power density of the zirconium target is 0.5 W/cm² to 3.0 W/cm²;
the target materials include an alloy target including at least two metallic elements in the Cr—Zr—N alloy coating; optionally, the target materials include a chromium-zirconium-based alloy target which has a power density of 4 W/cm² to 6 W/cm²;
a bias voltage of the substrate is −150 V to −20 V;
the sputter deposition is performed for 10 min to 150 min;
the nitrogen-containing gas is the nitrogen gas, and a gas flow rate of the nitrogen gas is 5 sccm to 52 sccm; and
the nitrogen-containing gas is the nitrogen gas, and a gas volume ratio of argon gas to nitrogen gas in the mixed gas is 2:1 to 6:1.

The details of one or more embodiments of the present application are set forth in the accompanying drawings and the description below. Other features, objects, and advantages of the present application will be apparent from the description and drawings, and from the claims.

### BRIEF DESCRIPTION OF THE ACCOMPANY DRAWINGS

In order to illustrate more clearly the technical solutions of the embodiments and examples of the present application and to understand more completely the present application and beneficial effects thereof, accompanying drawings to be used in the description of the embodiments and examples is briefly described herein. Apparently, the accompanying drawings in the following description merely represent some embodiments described in the present application. Based on these accompanying drawings, one skilled in the art can also obtain other drawings without making any inventive effort. It should also be noted that the drawings are drawn in a simplified form only to facilitate and clearly assist in the description of the disclosure. Various dimensions of each component shown in the drawings are arbitrarily illustrated and may be accurate or may not be drawn to scale. For example, to make the illustration clearer, the dimensions of components are appropriately exaggerated in some places in the drawings. Various components of the drawings are not drawn to scale unless specifically indicated. Not every dimension of every component is limited in the present application.

In the following description, the same reference signs denote the same parts.

FIG. 1 is a schematic structural diagram of an exemplary alloy film product including a Cr—Zr—N alloy material of the present application in an embodiment of the present application, which includes a substrate and an exemplary Cr—Zr—N alloy coating of the present application.

FIGS. 2A to 2C show schematic structural diagrams of alloy film products in some embodiments of the present application: (FIG. 2A) including a substrate, a transition layer, and an exemplary Cr—Zr—N alloy coating of the present application; (FIG. 2B) including a substrate, a transition layer, an exemplary Cr—Zr—N alloy coating of the present application and a surface layer; (FIG. 2C) including a substrate, an exemplary Cr—Zr—N alloy coating of the present application and a surface layer.

FIG. 3 is a schematic diagram of a device for preparing a Cr—Zr—N alloy coating of the present application in an embodiment of the present application.

FIG. 4 is an SEM cross-sectional image of Cr_{81.6}Zr_{13.7}N_{4.7} alloy coating prepared in Example 1 of the present application.

FIGS. 5A to 5C show an XRD pattern (FIG. 5A), a selected area electron diffraction (SAED) pattern (FIG. 5B), and a radial intensity profile (FIG. 5C) corresponding to the SAED pattern, of Cr_{81.6}Zr_{13.7}N_{4.7} alloy coating prepared in Example 1 of the present application.

FIG. 6 shows an SEM cross-sectional image of Cr_{61.4}Zr_{33.2}N_{5.4} alloy coating prepared in Example 2 of the present application.

FIGS. 7A to 7C show an XRD pattern (FIG. 7A), a selected area electron diffraction (SAED) pattern (FIG. 7B), and a radial intensity profile (FIG. 7C) corresponding to the SAED pattern, of Cr_{61.4}Zr_{33.2}N_{5.4} alloy coating prepared in Example 2 of the present application.

FIG. 8 is an SEM cross-sectional image of Cr_{47.1}Zr_{17.4}N_{35.5} alloy coating prepared in Example 3 of the present application.

FIG. 9 is an XRD pattern of Cr_{47.1}Zr_{17.4}N_{35.5} alloy coating prepared in Example 3 of the present application.

FIG. 10 is an SEM cross-sectional image of Cr_{52.0}Zr_{12.1}N_{35.9} alloy coating prepared in Example 4 of the present application.

FIG. 11 is an XRD pattern of Cr_{52.0}Zr_{12.1}N_{35.9} alloy coating prepared in Example 4 of the present application.

FIG. 12 is an SEM cross-sectional image of Cr_{60.9}Zr_{26.1}N₁₃ alloy coating prepared in Example 5 of the present application.

FIGS. 13A to 13C show an XRD pattern (FIG. 13A), a selected area electron diffraction (SAED) pattern (FIG. 13B), and a radial intensity profile (FIG. 13C) corresponding to the SAED pattern, of Cr_{60.9}Zr_{26.1}N₁₃ alloy coating prepared in Example 5 of the present application.

FIG. 14 is an SEM cross-sectional image of Cr_{60.9}Zr_{26.1}N₁₃ alloy coating prepared in Example 6 of the present application, wherein the Cr—Zr—N alloy coating serves as a lower layer of a double-layer structure coating, and a titanium nitride coating serving as a surface layer is provided above the alloy coating.

FIG. 15 is an SEM cross-sectional image of Cr_{60.9}Zr_{26.1}N₁₃ alloy coating prepared in Example 7 of the present application, wherein a Cr layer as a transition layer in contact with the Cr—Zr—N alloy coating is provided between the substrate and the Cr—Zr—N alloy coating, and a titanium nitride coating as a surface layer is also provided above the Cr—Zr—N alloy coating; the alloy film product has a protection structure in a sandwich form, with the Cr—Zr—N alloy coating serving as a middle structural layer of the three-layer-structure coating.

FIGS. 16A to 16C show an XRD pattern (FIG. 16A), a selected area electron diffraction (SAED) pattern (FIG. 16B), and a radial intensity profile (FIG. 16C) corresponding to the SAED pattern, of Cr_{49.5}Zr_{19.0}N_{32.5} alloy coating prepared in Example 13 of the present application.

FIG. 17 is an SEM cross-sectional image of Cr_{88.9}Zr_{11.1} alloy coating prepared in Comparative Example 1 of the present application.

FIG. 18 is an SEM cross-sectional image of Cr_{37.8}Zr_{16.2}N₄₆ alloy coating prepared in Comparative Example 2 of the present application.

FIG. 19A to 19C show an XRD pattern (FIG. 19A), a selected area electron diffraction (SAED) pattern (FIG. 19B), and a radial intensity profile (FIG. 19C) corresponding to the SAED pattern, of Cr_{37.8}Zr_{16.2}N₄₆ alloy coating prepared in Comparative Example 2 of the present application.

FIGS. 20A to 20C show an XRD pattern (FIG. 20A), a selected area electron diffraction (SAED) pattern (FIG. 20B), and a radial intensity profile (FIG. 20C) corresponding to the SAED pattern, of Cr_{39.6}Zr_{19.4}N₄₁ alloy coating prepared in Comparative Example 4 of the present application.

Description of reference signs: 1—vacuum chamber, 2—sample stage, 3—electrical circuit connecting the sample stage to a direct-current power supply, 4—chromium target (also referred to as Cr target), and 5—zirconium target (also referred to as Zr target);

100—substrate, 200—transition layer (also referred to as transition film layer), 300—Cr—Zr—N alloy coating, and 400—surface layer (also referred to as surface film layer). In the present application, unless otherwise specified, the chromium target 4 is a Cr target driven by a direct-current power supply assisted by a radio-frequency power supply, and the zirconium target 5 is a Zr target driven by a direct-current power supply assisted by a radio-frequency power supply.

### DETAILED DESCRIPTION

The present application is described in further detail below in conjunction with accompanying drawings, embodiments and examples. It should be understood that these embodiments and examples are only used to illustrate the present application and are not intended to limit the scope of the present application, and that they are provided for the purpose of enabling a more thorough and comprehensive understanding of the disclosure of the present application. It should also be understood that the present application can be realized in many different forms and is not limited to the embodiments and examples described herein, and the person skilled in the art can make various changes or modifications without departing from the connotation of the present application, and the equivalent forms obtained also fall within the protection scope of the present application. For example, features illustrated or described as part of one embodiment may be incorporated into another embodiment in a suitable manner to produce a new embodiment. Furthermore, in the description below, a great deal of detail is given to provide a fuller understanding of the present application, and it should be understood that the present application can be implemented without one or more of these details.

Unless otherwise defined, all technical and scientific terms used herein have the same meaning as commonly understood by those skilled in the art belonging to the present application. The terms used herein in the specification of the present application are used only for the purpose of describing embodiments and examples and are not intended to limit the present application.

### Terminology

Unless otherwise stated or there is a contradiction, terms or phrases used herein have the following meanings.

The terms “and/or”, “or/and”, and “as well as/or” used herein include any one of two or more relevant listed items, and include any and all combinations of the relevant listed items. The term “any and all combinations” includes any two of relevant listed items, any more of relevant listed items, or a combination of all relevant listed items. For example, “A and/or B” includes three parallel solutions: A, B and the combination of A and B

In the present application, “a plurality of”, “more”, “multiple”, and the like refer to a quantity greater than 2 or equal to 2, unless otherwise specified. For example, “one or more” means one, or equal to or more than two.

In the present application, “one or more” means any one of the listed items or any combination of the listed items unless otherwise specified. Similarly, when “one or more” and the like are used to mean “one or more”, they are to be understood in the same way unless otherwise specified.

As used herein, “a combination thereof”, “any combination thereof”, “any combination manner thereof”, and the like include all suitable combinations of any two or more of the listed items.

Herein, the “suitable” in “suitable combination manner”, “suitable manner”, “any suitable manner”, and the like, is based on being able to implement the technical solutions of the present application, solve the technical problems of the present application, and realize the expected technical effects of the present application.

Herein, the “preferred”, “preferably”, “better”, and “appropriate” are only used to describe an embodiment or example with better effect and should be understood as not constituting a limitation on the protection scope of the present application. If there are multiple “preferably” in a technical solution, in the case of no contradictions or mutual constraints, each “preferably” is independent, unless otherwise stated.

In the present application, the “further”, “furthermore”, “particularly”, “for example”, “such as”, “example”, “for instance”, and the like are used for descriptive purposes, indicating that the previous and subsequent technical solutions are related in terms of the content encompassed, but should not be understood as a limitation on the previous technical solution, nor can it be understood as a limitation on the scope of protection of the present application. In the present application, “A (such as B)” means that B is a non-limiting example of A, and it can be understood that A is not limited to B, unless otherwise specified.

In the present application, “optionally”, and “optional” means either with or without, i.e., either of the two parallel solutions of “with” or “without”. If there is more than one “optional” in a technical solution, each “optional” is independent of another, if not otherwise specified and if there are no contradictions or mutual constraints. In the present application, descriptions such as “optionally contain” and “optionally include” mean “contain or do not contain”. “Optional component X” means that component X is present or absent.

In the present application, the terms “first”, “second”, “third”, “fourth”, etc., in “first aspect”, “second aspect”, “third aspect”, “fourth aspect”, etc., are only used for descriptive purposes and are not to be construed as indicating or implying relative importance or quantity, or as implicitly specifying the importance or quantity of the technical features indicated. Moreover, “first”, “second”, “third”, “fourth” and the like only serve the purpose of non-exhaustive enumeration, and it should be understood that they do not constitute a closed-ended limitation of the quantity.

As used in the present application, the terms “comprising,” “including,” and “containing” are synonymous and are inclusive or open-ended and do not exclude additional, non-recited members, elements, or method steps.

In the present application, among the technical features described in an open-ended manner, a closed-ended technical solution consisting of the enumerated features is included, and an open-ended technical solution comprising the enumerated features is also included.

In the present application, when referring to a numerical interval (i.e., a numerical range), unless otherwise specified, the distribution of optional numerical values within the numerical interval is deemed to be continuous and includes the two numerical endpoints of the numerical interval (i.e., the minimum value and the maximum value), as well as each numerical value between the two numerical endpoints. Unless otherwise specified, when a numerical range refers only to integers within the numerical range, it includes the two endpoint integers of the numerical range and every integer between the two endpoints, which is equivalent to directly listing every integer. When multiple numerical ranges are provided to describe the feature or characteristic, the ranges may be combined. In other words, unless otherwise indicated, the ranges disclosed herein should be understood to include any and all sub-ranges subsumed therein. A “value” in the value range can be any quantitative value, such as a number, percentage, ratio, etc. “Numeric interval” allows broadly including percentage interval, proportion interval, ratio interval and other numerical interval types.

As used herein, unless otherwise specified, “about” means within a certain range above or below the number, and the fluctuation range may vary depending on the type and value of the number. For example, fluctuations in the range of ±2%, ±1%, ±0.5% of the original number are allowed. For example, about 2° means that the value can be selected from 2°±0.02°, etc.

In the present application, the temperature parameters allow for both constant temperature treatment and variations within a certain temperature range, unless otherwise specified. It should be understood that the constant temperature treatment allows the temperature to fluctuate within the precision of the instrument control. Fluctuations in the range of: ±5 °C, ±4 °C, ±3 °C, ±2 °C, and ±1 °C are allowed. The temperature unit °C refers to “degrees Celsius”.

In the present application, the term “room temperature” generally refers to 4 °C to 35 °C, for example 20 °C±5 °C. In some embodiments of the present application, “room temperature” refers to 10 °C to 30 °C. In some embodiments of the present application, “room temperature” refers to 20 °C to 30 °C.

In the present application, the term “normal temperature” generally refers to 20 °C to 35 °C, for example 20 °C to 35 °C. In some embodiments of the present application, “normal temperature” refers to 30 °C to 35 °C. In some embodiments of the present application, “normal temperature” refers to 30 °C.

In the present application, when referring to the unit of a data range, if a unit is only recited after the right endpoint, it means that the unit of the left endpoint is the same as that of the right endpoint. For example, 3 to 5 h means that the units of the left endpoint “3” and the right endpoint “5” are both h (hours), which has the same meaning as 3 h to 5 h. In addition, similar descriptions involving other parameters such as temperature and size also apply to the above understanding.

All documents mentioned in the present application are incorporated by reference into this application as if each was individually incorporated by reference. Unless they conflict with the invention purpose and/or technical solution of this application, the cited documents involved in the present application are cited with all contents and for all purposes. When the present application involves cited documents, the definitions of relevant technical features, terms, nouns, phrases, and the like in the cited documents are also cited. When the present application involves the cited documents, the cited examples and preferred ways of the relevant technical features may also be incorporated into the present application as references, but only to the extent that the present application can be implemented. It should be understood that when the cited contents conflict with the description in the present application, the present application shall prevail, or adaptive amendments shall be made according to the description in the present application.

The mass or weight of the relevant components mentioned in the embodiments or examples of the present application may not only refer to the specific content of each component, but also indicate the proportional relationship of the mass or weight between the components. Therefore, the content obtained by proportionally enlarging or reducing the contents of the relevant components in the embodiments or examples of the present application are also within the scope disclosed in the embodiments or examples of the present application. The unit of mass or weight in the embodiments or examples of the present application can be well known in the chemical industry such as microgram (μg), milligram (mg), gram (g), kilogram (kg), etc.

In the present application, if a method or process involves multiple steps, there is no strict order restriction for the execution of these steps, and they can be executed in other orders than described, unless otherwise clearly stated herein. Moreover, any step may include multiple sub-steps or multiple stages. These sub-steps or stages do not necessarily have to be executed at the same time but can be executed at different times. The order of execution is not necessarily sequential, but can be executed in turn, alternating or simultaneously with other steps or parts of sub-steps or stages of other steps.

In describing positional relationships, unless otherwise specified, when an element, such as a layer, a film, or a substrate, is referred to as being “above” another film or layer, it can be directly above the other layer, or there may be an intermediate layer. Furthermore, when a layer is referred to as being “under” another layer, it may be directly under the other layer, or there may be one or more intermediate layers. It will also be appreciated that when a layer is referred to as being “between” two layers, it may be the only layer between the two layers, or there may be one or more intermediate layers.

Where “including,” “having,” and “comprising” are used herein, it is intended to cover a non-exclusive inclusion, and another component may also be added unless explicit limiting terms such as “only,” “consisting of,” etc. are used.

Unless mentioned to the contrary, a term in a singular form may include a plural form and cannot be understood as one in quantity.

In the present application, exemplary descriptions such as “in some embodiments (or examples)” and “in one embodiment (or example)” may include but are not limited to the following meanings: these solutions may be combined with other solutions in a suitable manner to form new technical solutions.

Conventional Cr—Zr—N alloy coatings are typically in nanocrystalline state and have a high content of columnar crystals. On the one hand, it is often difficult to achieve a high value for L value of these alloy coatings, and the L value is usually about 55 to 65. On the other hand, the high content of columnar crystals in these alloy coatings promotes the formation of a directional arrangement into a highly ordered structure. In the highly ordered structure, there are a large number of inter-crystal gap defects caused by crystallization, which are mainly manifested as penetrating columnar gaps. The corresponding scanning electron microscopy (SEM) cross-sectional images show shadows between the columnar crystals. These penetrating columnar gaps may be one of the important factors leading to the poor corrosion resistance of the alloy coating. The inventors of the present application speculate that the conventional directional ordered structure may easily lead to an insufficiently dense coating. Under corrosive conditions, the corrosive medium can quickly penetrate the coating through the penetrating gaps and react with the substrate, thereby resulting in poor corrosion resistance of the alloy coating.

In addition, for the alloy materials currently on the market, methods such as anodic oxidation and magnetron sputtering are mainly used for surface protection. For example, surface protection for aluminum alloys is mainly conducted through anodic oxidation which works as follows: the aluminum alloy material is placed in a strong acid or strong alkali solution to form oxides and metal and alloy coatings on the surface to form the surface protection. Because the solution is a strong acid or strong alkali, the product formed by this method has insufficient gloss and low hardness. In addition, a large amount of wastewater, waste liquid and waste gas would be generated in the production process, which is not good for the environment.

According to various embodiments and examples of the present application, one aspect of the present application provides a Cr—Zr—N alloy material. The Cr—Zr—N alloy material can form a Cr—Zr—N alloy coating with both high brightness and high corrosion resistance. When the Cr—Zr—N alloy coating is disposed on the surface of the alloy film product, it can render the alloy film product to have both high brightness and high corrosion resistance. In addition, other aspects of the present application also provide a Cr—Zr—N alloy coating and an alloy film product, and also provide an application of the aforementioned Cr—Zr—N alloy material or Cr—Zr—N alloy coating in a high-brightness surface coating and a method for preparing the Cr—Zr—N alloy coating.

The Cr—Zr—N alloy material provided in the present application mainly includes three elements: chromium (Cr), zirconium (Zr), and nitrogen (N). These three elements have specific relative atomic ratios (CrₓZr_{y}N_{z}), wherein 47.1≤x≤81.6, 12.1≤y≤33.2, and 4.7≤z≤35.9. Thus, the Cr—Zr—N alloy material has the ability to form a highly disordered atomic distribution and a sufficiently densely packed atomic arrangement and can form a Cr—Zr—N alloy coating with a dense structure. When the Cr—Zr—N alloy coating is disposed on the surface of the product, it can not only give the product a beautiful high-brightness surface, but also provide excellent corrosion resistance. In corrosion resistance evaluation by salt spray test, a protection time of the Cr—Zr—N alloy coating containing the Cr—Zr—N alloy material of the present application is much longer than that of the conventional Cr—Zr—N alloy coating.

In addition, the Cr—Zr—N alloy coating provided in the present application not only provides excellent corrosion resistance, but also has high hardness, thereby better reducing the occurrence of scratches or weakening scratch damage. Further, the Cr—Zr—N alloy coating provided in the present application can exhibit both high corrosion resistance and high hardness at a relatively low thickness, thereby saving raw materials, simplifying the process, shortening the production cycle, and significantly reducing costs.

The Cr—Zr—N alloy coating provided in the present application can be used as a surface layer of the alloy film product and has both beautiful decorative effect and protection effect. The Cr—Zr—N alloy coating provided in the present application can also be located between the substrate and the surface layer of other structures to provide excellent protection effect, thereby better resisting corrosion and scratches.

The Cr—Zr—N alloy coating provided in the present application can be applied to a variety of substrates. The materials of the substrates include but are not limited to an alloy, an elemental metal, a non-metallic inorganic material, and other materials.

When the Cr—Zr—N alloy coating of the present application is provided in the protective coating of the alloy film product, the Cr—Zr—N alloy coating can be flexibly arranged in various positions. For example, the Cr—Zr—N alloy coating can be used for surface protection, in which case the Cr—Zr—N alloy coating is disposed on a surface of the alloy film product, for providing a high-brightness surface for the alloy film product; the Cr—Zr—N alloy coating can also be used as an intermediate protective layer, in which case other structural layers are provided on the outside of the Cr—Zr—N alloy coating, that is, the Cr—Zr—N alloy coating may not serve as a surface layer. The Cr—Zr—N alloy coatings at different positions can achieve relatively good scratch resistance and relatively good corrosion resistance.

The method for preparing the Cr—Zr—N alloy coating provided in the present application is simple, easy to operate, green and environmentally friendly, and has the advantages of being quantifiable, highly efficient, and repeatable, and thus is suitable for industrial applications.

In a first aspect of the present application, a Cr—Zr—N alloy material is provided. The Cr—Zr—N alloy material is represented by a chemical formula of (CrₓZr_{y}N_{z})Mₐ, where M is a doping element, wherein x, y, z, and a are each independently atomic ratios, 47.1≤x≤81.6, 12.1≤y≤33.2, 4.75≤z≤35.9, and 0≤a/(x+y+z+a)≤0.05. The Cr—Zr—N alloy material can provide a Cr—Zr—N alloy coating having both a high-brightness surface and excellent corrosion resistance, and can be used to prepare an alloy film product having the Cr—Zr—N alloy coating of the present application.

The Cr—Zr—N alloy material provided in one aspect of the present application may also be recited as the “present Cr—Zr—N alloy material”, “Cr—Zr—N alloy material of the present application”, “exemplary Cr—Zr—N alloy material of the present application” or “Cr—Zr—N alloy material provided in the present application”, and includes but is not limited to the Cr—Zr—N alloy material provided in the first aspect. Each of the above citations should be understood in a non-limiting manner and should not be understood as limiting the scope of the present application. For example, the scope of the present application is not limited to “the present Cr—Zr—N alloy material”. The descriptions of “the present Cr—Zr—N alloy material” and the like in the present application are to be non-restrictively understood as an exemplary Cr—Zr—N alloy material provided in one aspect of the present application, and do not limit the scope of the Cr—Zr—N alloy material provided in the present application.

The Cr—Zr—N alloy coating provided in one aspect of the present application may also be recited as the “present Cr—Zr—N alloy coating”, “Cr—Zr—N alloy coating of the present application”, “exemplary Cr—Zr—N alloy coating of the present application” or “Cr—Zr—N alloy coating provided in the present application”, and includes but is not limited to the Cr—Zr—N alloy coating provided in the first aspect. Each of the above citations should be understood in a non-limiting manner and should not be understood as limiting the scope of the present application. For example, the scope of the present application is not limited to “the present Cr—Zr—N alloy coating”. The descriptions of “the present Cr—Zr—N alloy coating” and the like in the present application are to be non-restrictively understood as an exemplary Cr—Zr—N alloy coating provided in one aspect of the present application, and do not limit the scope of the Cr—Zr—N alloy coating provided in the present application.

In the present application, “Cr—Zr—N alloy” and “CrZrN alloy” both refer to alloys containing chromium (Cr), zirconium (Zr), and nitrogen (N) elements, in which other alloying elements may also be contained, unless otherwise specified. “Cr—Zr—N alloy” and “CrZrN alloy” can be used interchangeably.

In the present application, “Cr—Zr—N alloy material” refers to alloy material containing Cr, Zr, and N elements, unless otherwise specified. In the Cr—Zr—N alloy material provided in the present application, the three elements Cr, Zr, and N have a specific atomic ratio x:y:z, as described above. In the present application, the form of the Cr—Zr—N alloy material is not particularly limited, and may be, but is not limited to, an alloy coating form.

In the present application, the “atomic ratio” of two or more elements means the atomic number ratio, unless otherwise specified.

In the present application, “Cr—Zr—N ternary alloy” and “CrZrN ternary alloy” both refer to an alloy consisting of three elements: Cr, Zr, and N, unless otherwise specified.

The Cr—Zr—N alloy material provided in the present application mainly includes three elements: Cr, Zr, and N. These three elements have specific relative atomic ratios (CrₓZr_{y}N_{z}), wherein 47.1≤x≤81.6, 12.1≤y≤33.2, and 4.7≤z≤35.9. Thus, the Cr—Zr—N alloy material can form a highly disordered atomic distribution and a sufficiently densely packed atomic arrangement, and can form a Cr—Zr—N alloy coating with a dense structure. When the Cr—Zr—N alloy coating of the present application is disposed on the surface of the product, it can not only give the product a beautiful high-brightness surface, but also provide excellent corrosion resistance. In corrosion resistance evaluation by salt spray test, a protection time of the Cr—Zr—N alloy coating containing the Cr—Zr—N alloy material of the present application is much longer than that of the conventional Cr—Zr—N alloy coating.

Conventional Cr—Zr—N alloy coatings are typically nanocrystalline, have a high content of columnar crystals, and exhibit noticeable penetrating pores, which on the one hand leads to poor surface reflection and low brightness, and on the other hand leads to poor corrosion resistance. In contrast, the Cr—Zr—N alloy material provided in the present application can form a dense coating having a “highly disordered and sufficiently densely packed” structure with very few penetrating pores or even no penetrating pores. Cr, Zr, and N (three atoms with different radius) have a special atomic ratio, which facilitates the atoms to condense into a highly disordered and sufficiently densely packed structure during deposition, and thus form a dense, high-brightness surface with relatively good reflection characteristics, which facilitates the alloy coating to densely grow, thereby inhibiting the formation of a large numbers of continuous penetrating gaps, and thus effectively isolating the substrate from corrosive environments. Moreover, the Cr—Zr—N alloy coating provided in the present application are still rich in chromium and zirconium elements, and therefore fully chemically inert in the corrosive environment. The Cr—Zr—N alloy material provided in the present application can form a Cr—Zr—N alloy coating that shows atoms that are highly disorderedly distributed and sufficiently densely packed, which avoids or reduces the formation of penetrating gaps caused by highly ordered arrangement. The characteristics of “both highly disorderedly distributed” and “sufficiently densely packed” of atoms in the alloy coating leads to the alloy coating to have a highly dense structure, which provides both high-brightness surface and excellent corrosion resistance.

In the Cr—Zr—N alloy material and Cr—Zr—N alloy coating of the present application, a high content of Cr is used, and Zr and N are introduced based on the special atomic ratio of Cr, Zr, and N, making Cr and Zr easy to form a relatively strong bond energy, which is beneficial to promoting the rapid growth of a Cr—Zr alloy with a suitable atomic ratio during the deposition process. The addition of an appropriate amount of nitrogen further promotes the re-nucleation of the Cr—Zr alloy to form the Cr—Zr—N alloy of the present application. By increasing the density of the coating nucleation, the brightness and corrosion resistance of the coating as well as the hardness of the coating can be improved. In terms of atomic size, the atomic radius of Cr is 1.25 Å, the atomic radius of Zr is 1.60 Å, and the atomic radius of N is 0.71 Å. The atomic size of Cr is close to that of Zr, and the atomic size of N is smaller. During the nucleation process, an appropriate amount of small-sized N atoms can penetrate into the pores of large-sized Cr and Zr metal crystalline grains in an appropriate atomic ratio, achieving a relatively good pore-filling effect, making the atoms arranged more densely, and also inhibiting the growth defects of the columnar crystal structure of the film, thereby better improving the brightness and corrosion resistance of the coating, and also better improving the hardness of the coating.

Cr is a high-brightness metal raw material in the coating material. A higher Cr content can effectively improve the brightness of the alloy coating. Meanwhile, the Cr—Zr—N alloy material of the present application can be made into a Cr—Zr—N alloy coating of the present application with high density, which further improves the surface reflection characteristics of the coating. The superposition of these two characteristics makes the coating surface brighter during the chroma value measurement; that is the brightness value (i.e., L value) is higher. The L values of the Cr—Zr—N alloy coatings of the present application can be ≥70, and some of them can be up to 81, with presenting a high-brightness silver-white color, which are much higher than the L values of the conventional alloy coatings approximately ranging from 55 to 65. The high-brightness coating has an aesthetic effect and excellent decorative properties. When the high-brightness coating is applied to the surface of a substrate (such as pure metals, alloys, and other materials), a high-brightness aesthetic effect can be achieved, making the color of the coating closer to the color of the substrate, so that a surface without color difference can be realized. This property makes the Cr—Zr—N alloy coating provided in this application have an excellent decorative effect, which is particularly suitable for but not limited to 3C digital products such as mobile phone components to achieve a high-gloss metal effect, and can be applied to wearable products, automotive products, sport products and other fields.

When the chroma value of alloy coating is tested, a sample to be tested adopted a substrate material suitable for actual application. L, a, and b values of the sample can be tested by using a CM-3700A-U desktop spectrophotometer (Konica, Japan), with a F2 light source used as a light receiving system. Each sample is tested for 6 matrix points, and an average value is calculated. L value represents the brightness value, a value represents the red, green chroma values, and b value represents the yellow, blue chroma values. A larger L value indicates a higher brightness, suggesting a denser coating surface. The mechanism is as follows: in the spectrophotometer, an incident light hits the surface of the sample to be tested to form a reflection, and thus to obtain a reflectance curve. The amplitude of the curve can reflect the density of the material, which can be characterized by the L value. For the same material, the higher the density, the larger the L value it displays.

Cr—Zr—N alloy material provided in the present application shows atoms that are highly disorderedly distributed and highly densely packed arranged, thereby realizing densely packing of atoms under highly disordered atomic arrangement, so that the formed Cr—Zr—N alloy coating has a special “highly disordered and sufficiently densely packed” atomic arrangement, which avoids or reduces the formation of penetrating pores caused by interconnection of inter-granular gaps due to highly ordered arrangement, and thus endows the alloy coating with a highly dense structure, leading to a high-brightness surface with relatively good reflection properties and excellent corrosion resistance. In the present Cr—Zr—N alloy coating prepared with the Cr—Zr—N alloy material, defects commonly present in conventional alloy coatings are significantly reduced, such as through-grain-boundary gaps among crystallites are significantly reduced or eliminated in the columnar crystal-structured coating, so that the Cr—Zr—N alloy coating advantageously obtains dense and flat high-brightness surface, and is provided with excellent corrosion resistance.

In addition, the Cr—Zr—N alloy coating prepared by using the Cr—Zr—N alloy material of the present application has a dense structure, which provides not only excellent corrosion resistance but also high hardness, thereby better reducing the occurrence of scratches or weakening scratch damage. Further, the Cr—Zr—N alloy coating provided in the present application can have both high corrosion resistance and high hardness at a relatively low thickness, thereby saving raw materials, simplifying the process, shortening the production cycle, and significantly reducing costs.

The Cr—Zr—N alloy coating prepared by using the Cr—Zr—N alloy material provided in the present application can be used as a surface layer of the alloy film product and display both beautiful decorative effect and protection effect. The Cr—Zr—N alloy coating provided in the present application can also be located between the substrate and a surface layer to provide excellent protection effect, thereby better resisting corrosion and scratches.

In some embodiments, in the case where the proportion relationship of 47.1≤x≤81.6, 12.1≤y≤33.2, and 4.7≤z≤35.9, and x+y+z=100 are met, x can be any value of, or can be selected from intervals defined by any two values of: 47.1, 52.0, 53.8, 54.8, 60.9, 61.4, 81.6, etc.

In some embodiments, in the case where the proportion relationship of 47.1≤x≤81.6, 12.1≤y≤33.2, and 4.7≤z≤35.9, and x+y+z=100 are met, y can be any value of, or can be selected from intervals defined by any two values of: 12.1, 13.0, 13.7, 17.4, 26.1, 30.0, 33.2, etc.

In some embodiments, in the case where the proportion relationship of 47.1≤x≤81.6, 12.1≤y≤33.2, and 4.7≤z≤35.9, and x+y+z=100 are met, z can be any value of, or can be selected from intervals defined by any two values of: 4.7, 5.4, 6.2, 10.1, 13.0, 20.2, 25.5, 35.5, 35.9, etc.

In some embodiments, a sum of x, y, and z is 100. In this case, x, y, and z respectively correspond to atomic ratios of the three elements Cr, Zr, and N. In this case, the ratio of the three atoms Cr, Zr, and Nis constrained within a more appropriate range, so that the prepared Cr—Zr—N alloy coating is inclined to form a denser structure, which is beneficial to achieving better brightness and better corrosion resistance. In addition, the hardness of the coating can be beneficially improved.

The Cr—Zr—N alloy material and Cr—Zr—N alloy coating provided in the present application may or may not contain a doping element, and it can be flexibly selected according to the additional functional requirements for the alloy material and/or the alloy coating. It can be understood that in the present application, when a doping element is contained, the type and doping amount of the doping element are limited by not affecting the high brightness and corrosion resistance of the Cr—Zr—N alloy coating.

In the present application, the chemical formula of the Cr—Zr—N alloy material can be represented by (CrₓZr_{y}N_{z})Mₐ, wherein x, y, and z are each independently atomic ratios and are positive numbers, M is the doping element, and a is the atomic ratio of the M element and is 0 or a positive number. During the nucleation process, N atoms can penetrate the pores of large-sized Cr and Zr metal crystalline grains, achieving a better pore-filling effect, making the coating atoms stacked more densely, and inhibiting the growth defects of the columnar crystal structure of the film, thereby improving the corrosion resistance of the coating.

When a is 0, the Cr—Zr—N alloy material does not contain a doping element, corresponding to a Cr—Zr—N ternary alloy material. When a>0, the Cr—Zr—N alloy material contains a doping element, wherein a/(x+y+z) is numerically equal to the “relative atomic ratio of the doping element to Cr, Zr, and N”, and a/(x+y+z+a) is numerically equal to the “atomic ratio of the doping element in the Cr—Zr—N alloy material”. The “relative atomic ratio of the doping element M relative to Cr, Zr, and N” refers to a ratio of the number of atoms of the doping element M to the sum of the number of atoms of Cr, Zr, and N in the material, expressed in percentage.

Unless otherwise specified, the Cr—Zr—N alloy material provided in the present application mainly contains three elements: Cr, Zr, and N. Furthermore, a sum of atomic ratios of the three elements accounts for ≥95% of a sum of atomic ratios of all elements in the Cr—Zr—N alloy material (corresponding to 0≤a/(x+y+z+a)≤0.05, further such as 0≤a/(x+y+z)≤0.05), and further for example, accounts for ≥98% (corresponding to 0≤a/(x+y+z+a)≤0.02, further such as 0≤a/(x+y+z)≤0.02). Further, for example, the Cr—Zr—N alloy material is a Cr—Zr—N ternary alloy material (in this case, a=0). By limiting the content of doping element, the influence of doping element on the highly disordered and sufficiently densely packed atoms in the Cr—Zr—N alloy coating of the present application can be minimized, which is beneficial to reducing the elements required for doping or reducing the difficulty of doping, simplifying the preparation process, and promoting the synergistic deposition of Cr, Zr, and N to form a denser coating, which is beneficial to achieving better corrosion resistance and to achieving higher hardness.

In some embodiments, a/(x+y+z)=0. In this case, it corresponds to the Cr—Zr—N ternary alloy material, which has a simple composition and is easier to prepare and manipulate. In this case, the Cr—Zr—N ternary alloy coating can obtain a dense structure, which can achieve high brightness and high corrosion resistance. In addition, higher coating hardness can also be obtained.

In some embodiments, 0<a/(x+y+z+a)≤0.05. The ratio of a/(x+y+z+a) can also be any of, can be greater than 0 and less than or equal to any of, or can be selected from a numerical interval between any two of: 0.0001, 0.0005, 0.001, 0.005, 0.01, 0.015, 0.02, 0.03, 0.04, 0.05, etc.

In some embodiments, 0<a/(x+y+z)≤0.05. The ratio of a/(x+y+z) can also be any of, can be greater than 0 and less than or equal to any of, or can be selected from a numerical interval between any two of: 0.0001, 0.0005, 0.001, 0.005, 0.01, 0.015, 0.02, 0.03, 0.04, 0.05, etc.

In some preferable embodiments, 0<a/(x+y+z+a)≤0.02, further, for example, 0<a/(x+y+z+a)≤0.02, 0≤a/(x+y+z+a)≤0.01, 0<a/(x+y+z+a)≤0.01, 0<a/(x+y+z+a)<0.01, etc. In some preferable embodiments, 0≤a/(x+y+z)≤0.02, further, for example, 0<a/(x+y+z)≤0.02, 0≤a/(x+y+z)≤0.01, 0<a/(x+y+z)≤0.01, 0<a/(x+y+z)<0.01, etc. In this case, the doping elements can be controlled at a relatively low content, so that the influence of doping elements on the highly disordered and sufficiently densely packed atoms in the Cr—Zr—N alloy coating can be minimized, which is beneficial to reducing the elements required for doping or reducing the difficulty of doping, simplifying the preparation process, and promoting the synergistic deposition of Cr—Zr—N to form a denser coating, which is beneficial to achieve higher brightness and better corrosion resistance. In addition, a higher coating hardness can also be beneficially obtained.

In some embodiments, y is greater than z based on any suitable embodiment described above. In this case, in the Cr—Zr—N alloy material provided in the present application, the Cr content is highest, followed by the Zr content, and the nitrogen content is lowest. This special atomic ratio design can effectively improve the density of the coating nucleation, thereby further improving the brightness value and corrosion resistance of the coating. In this case, during the nucleation process, N atoms can penetrate into the pores of large-sized Cr and Zr metal crystalline grains, achieving a relatively good pore-filling effect, making the coating atoms stacked more densely, and also effectively inhibiting the growth defects of the columnar crystal structure of the film, thereby effectively improving the surface reflection characteristics of the coating to increase the brightness value, and also significantly improving the corrosion resistance. In addition, a relatively good coating hardness can also be achieved.

In some embodiments, based on any suitable embodiment described above, 63.19−0.925y≤x≤95.79−y, and 31.4+0.9y≤x≤18.5y−171.85. In this case, the ratio of the three atoms Cr, Zr, and N is controlled within a better range, so that the prepared Cr—Zr—N alloy coating is inclined to form a denser structure, which is beneficial to achieving higher brightness and better corrosion resistance. In addition, better coating hardness can also be beneficially obtained.

In some embodiments, the doping element is a non-metallic element, a metallic element, or a combination thereof, which can be flexibly selected according to the additional functional requirements for the Cr—Zr—N alloy coating.

Without limitation, the non-metallic element may include one or more of O, C, B, Si, and Ar. Without limitation, the metallic element may include one or more of Ti, V, Nb, Mo, Hf, Ta, W, Ni, Mo, Fe, Ag, Au, Cu, and Al.

It should be noted that, in any embodiment of the present application, the Cr—Zr—N alloy material and Cr—Zr—N alloy coating provided in the present application are allowed to contain inevitable impurities introduced during the preparation process. “Inevitable impurities” are not intentionally added impurities, which are present mainly because they are unintentionally introduced during the preparation process. Non-limiting examples of “inevitable impurities” include elements such as C and O present in the air and may also be components that come from the raw materials or the equipment. The atomic contents of “inevitable impurities” in an alloy material or an alloy coating are usually in trace or minute amounts, which can generally be ignored, such as less than 0.01% atomic content. Taking the technical solution of “the Cr—Zr—N alloy coating being a Cr—Zr—N ternary alloy material consisting of Cr, Zr, and N elements” as an example, the Cr—Zr—N alloy coating is theoretically consisting of three elements: Cr, Zr, and N, however, in addition to Cr, Zr, and N, trace or minute amounts of other elements such as C, O, etc. may be introduced during the preparation process.

In a second aspect of the present application, a Cr—Zr—N alloy coating is provided. The Cr—Zr—N alloy coating includes a film layer formed with the Cr—Zr—N alloy material described in the first aspect of the present application. As explained before, based on the special atomic ratio of Cr, Zr, and N, the Cr—Zr—N alloy coating forms a highly disordered atomic distribution and a sufficiently densely packed atomic arrangement, and has a “highly disordered and sufficiently densely packed” dense coating structure, which can improve the surface reflection characteristics and increase brightness, and can also inhibit the formation of continuous and large numbers of penetrating gaps, significantly improving the corrosion resistance of the coating.

In addition, based on the improvement of the density of the coating structure, higher coating hardness can also be obtained. The Cr—Zr—N alloy coating provided in the present application has a dense structure, which provides not only excellent corrosion resistance but also high hardness, thereby reducing the occurrence of scratches or weakening scratch damage. Further, the Cr—Zr—N alloy coating provided in the present application can have both high corrosion resistance and high hardness at a relatively low thickness, thereby saving raw materials, simplifying the process, shortening the production cycle, and significantly reducing costs. The Cr—Zr—N alloy coating provided in the present application can be used as a surface layer of the alloy film product and has both beautiful decorative effect and the protection effect. The Cr—Zr—N alloy coating provided in the present application can also be located between the substrate and a surface layer to provide excellent protection effect, thereby better resisting corrosion and scratches.

In some embodiments, the Cr—Zr—N alloy coating satisfies the following two characteristics:
in an XRD pattern of the Cr—Zr—N alloy coating, there is a peak in a diffraction angle 2θ (°) range of 30° to 50°, and at least one 2θ (°) diffraction peak in the range of 30°to 50°has a full width at half maximum of ≥2°; and
in a radial intensity profile corresponding to a selected area electron diffraction pattern of the Cr—Zr—N alloy coating, with a characteristic interatomic spacing as a horizontal axis and a diffraction intensity as a vertical axis, there is a diffraction peak in the range of 2.0 Å to 3.0 Å, and at least one diffraction peak in the range of 2.0 Å to 3.0 Å has a full width at half maximum of ≥0.21 Å. The unit Å stands for “angstrom”.

The means for structural characterization of the Cr—Zr—N alloy coating in the present application can also be used to characterize the Cr—Zr—N alloy material in first aspect of the present application. The Cr—Zr—N alloy material may not be limited to the coating form, but may be independent raw material, such as an alloy sheet, an alloy plate, etc.

For example, in some embodiments, the Cr—Zr—N alloy material satisfies the following two characteristics:
in an XRD pattern of the Cr—Zr—N alloy material, there is a peak in a diffraction angle 2θ (°) range of 30° to 50°, and at least one 2θ (°) diffraction peak in the range of 30° to 50° has a full width at half maximum of ≥2°; and
in a radial intensity profile corresponding to a selected area electron diffraction pattern of the Cr—Zr—N alloy material, with a characteristic interatomic spacing as a horizontal axis and a diffraction intensity as a vertical axis, there is a diffraction peak in the range of 2.0 Å to 3.0 Å, and at least one diffraction peak in the range of 2.0 Å to 3.0 Å has a full width at half maximum of ≥0.21 Å.

Furthermore, the XRD results and the radial intensity profile results corresponding to the selected area electron diffraction pattern of the Cr—Zr—N alloy material can also refer to the description of the XRD pattern and the radial intensity profile corresponding to the selected area electron diffraction pattern for the Cr—Zr—N alloy coating in the context. The corresponding optional and preferred methods can also be applied to the Cr—Zr—N alloy material.

The Cr—Zr—N alloy coating provided in the present application cannot be clearly determined according to the conventional perfect single crystal state or fully amorphous state but focuses on the degree of densely packing of atomic arrangement. Based on the specific atomic ratio of Cr, Zr, and N, the degree of densely packing is closely related to the disorder of atomic arrangement and the appropriate mismatch of atomic size. The highly dense Cr—Zr—N alloy coating provided in the present application has a high brightness value and excellent corrosion resistance as well as high hardness in terms of performance; and in terms of structure, satisfies that: there is at least one broad peak in the diffraction angle 2θ (°) range of 30° to 50° (further, may have no sharp peak, that is peaks are all broad peaks) in the XRD pattern, and there is at least one broad peak in the range of 2.0 Å to 3.0 Å (further, may have no sharp peak, that is peaks are all broad peaks) in the radial intensity profile of the selected area electron diffraction pattern.

The conventional Cr—Zr—N alloy coatings which are nanocrystalline, have a high content of columnar crystals, and exhibit noticeable penetrating pores. In contrast, the Cr—Zr—N alloy coatings provided in the present application can form a dense coating having a “highly disordered and sufficiently densely packed” structure with very few penetrating pores or even no penetrating pores. In the alloy coating of the present application, Cr, Zr, and N (three atoms with different radius) condense into a highly disordered and sufficiently densely packed structure during deposition, and thus form a dense surface with good reflection characteristic and high brightness, which facilitates the alloy coating to densely grow, thereby inhibiting the formation of a large numbers of continuous penetrating gaps, and thus effectively isolating the substrate from corrosive environments. Moreover, the Cr—Zr—N alloy coating provided in the present application are still rich in chromium and zirconium elements, and therefore fully chemically inert in the corrosive environment. The Cr—Zr—N alloy material of the Cr—Zr—N alloy coating provided in the present application shows atoms that are highly disorderedly distributed and sufficiently densely packed, which avoids or reduces the formation of penetrating gaps caused by highly ordered arrangement. The characteristics of “both highly disorderedly distributed” and “sufficiently densely packed” of atoms in the alloy coating leads to the alloy coating to have a highly dense structure, which provides both high-brightness surface and excellent corrosion resistance.

In the present application, whether the constituent atoms of the alloy coating have a “highly disordered” state is evaluated by XRD. In more detail, the XRD pattern of the Cr—Zr—N alloy coating shows broad and gentle ridges, and these “broad and gentle ridges” are called “broad peaks” of the 2θ (°) diffraction peaks. Based on full width at half maximum values of the broad peaks, a length of ordered arrangement of atoms can be calculated with the Scherrer formula of D=Kλ/(β·cos θ), where D indicates the length of ordered arrangement of atoms, representing the crystalline grain size in crystalline materials, K is the Scherrer constant, λ is the wavelength of X-ray; β is the full width at half maximum (i.e., FWHM, referring to the width at half the height of the diffraction peak) value of the diffraction peak, and θ is the diffraction angle. It can be seen that the FWHM is inversely proportional to the length D of ordered arrangement of atoms. The shorter the length D of ordered arrangement of atoms, the higher the disorder of the atomic distribution. Therefore, the FWHM values of the diffraction peaks in a specific range in the XRD pattern can be used to reflect the degree of disordered distribution of atoms. That is, the wider the FWHM, the shorter the length of ordered arrangement of atoms, and the more disordered the overall atomic distribution. The “broad peak”, shown as the broad and gentle ridge, can reflect overall highly disordered distribution of atoms in the material.

Generally speaking, the higher the ordered arrangement of atoms, the stronger the crystallinity; the easier it is to form large-sized crystalline grains over a relatively long distance, and the narrower the diffraction peak in the XRD pattern. Consequently, high crystallinity is often accompanied by sharp peaks. In the alloy coating of the present application, the three kinds of atoms Cr, Zr, and N can be overall highly disordered in the Cr—Zr—N alloy coating, thereby showing broad and gentle ridges (i.e., broad peaks) in the XRD pattern of the Cr—Zr—N alloy coating and showing at least one “broad peak” in the diffraction angle 2θ (°) range of 30° to 50°,

In the present application, unless otherwise specified, a “broad peak” in an XRD pattern may be defined as a peak of which the full width at half maximum is ≥2°. Further, the full width at half maximum of the broad peak may be ≥2.19°; further ≥2.2°, further ≥2.3°, more further ≥3°, more further ≥3.5°, more further 24°; and more further ≥5°. The full width at half maximum of any “broad peak” in the XRD pattern can independently be any value of, can be greater than or equal to any value of, can be less than or equal to 10° and greater than or equal to any value (except 10°) of, or can be selected from a interval between any two of: 2°, 2.19°, 2.2°, 2.5°, 3°, 3.5°, 4°, 4.04°, 4.42°, 4.5°, 5°, 5.5°, 6°, 6.5°, 7°, 7.5°, 8.42°, 8.5°, 8.85°, 9°, 9.11°, 9.33°, 9.5°, 10°, etc. As a non-limiting example, the full width at half maximum of the broad peak can be any selected from the following ranges: 2° to 10°, 2°to 9.5°, 2° to 9.4°, 2.1° to 9.5°, 2.1° to 9.4°, 2.15° to 9.35°, 2.19° to 9.33°, etc.

In the present application, a “sharp peak” in an X-ray diffraction (XRD) pattern refers to a diffraction peak with a full width at half maximum of <2°, unless otherwise specified.

In more detail, in an XRD pattern of the Cr—Zr—N alloy coating provided in the present application, there is a peak in the diffraction angle 2θ (°) range of 30° to 50°, and at least one of the diffraction peaks in the XRD pattern is a broad peak. The special microstructural state in which at least one peak is a “broad peak” can be expressed by “there is at least one 2θ (°) diffraction peak having a full width at half maximum of ≥2° in the range of 30° to 50°” or “at least one 2θ (°) diffraction peak in the range of 30° to 50° has a full width at half maximum of ≥2°”. Whether “there is at least one 2θ (°) diffraction peak having a full width at half maximum of ≥2° in the range of 30° to 50°” can be determined as follows: in a XRD spectrum, if the full width at half maximum value of the 2θ (°) diffraction peak is ≥2°, the peak is identified as a “broad peak”; if the full width at half maximum value of the 2θ (°) diffraction peak is <2°, the peak is identified as a sharp peak. For a given 2θ (°) position, there may be any of three conditions: no peak, broad peak or sharp peak. In the X-ray diffraction (XRD) pattern of the Cr—Zr—N alloy coating provided in the present application, the broad peak characteristics of the characteristic diffraction peaks are relatively obvious.

In contrast, for conventional Cr—Zr—N alloy coatings with a high content of columnar crystals, the diffraction peak in the diffraction angle 2θ (°) range of 30° to 50° often appears as a sharp peak with a full width at half maximum of <2°, and no broad peak appears.

In the present application, conventional instruments and methods in the art may be used to obtain the XRD patterns of the alloy coatings. For example, a Bruker D8 ADVANCE XRD diffractometer from German may be used.

In some embodiments, in a XRD pattern of the Cr—Zr—N alloy coating provided in the present application, there is a peak in the diffraction angle 2θ (°) range of 30° to 50°, and at least one 2θ (°) diffraction peak in the range of 30° to 50° is a broad peak, and the FWHM of the broad peak can be referred to the examples in the context. Taking the broad peak having the FWHM of ≥2.19° as an example, at least one 2θ (°) diffraction peak in the range of 30° to 50° is ≥2.19°.

In some embodiments, in the XRD pattern of the Cr—Zr—N alloy coating of the present application, there is one broad peak in the diffraction angle 2θ (°) range of 30° to 50°, the full width at half maximum value of which can be referred to the examples in the context.

In some embodiments, in the XRD pattern of the Cr—Zr—N alloy coating of the present application, there are two or more broad peaks in the diffraction angle 2θ (°) range of 30° to 50°, the full width at half maximum values of which can each be independently referred to the examples in the context.

In some embodiments, in the XRD pattern of the Cr—Zr—N alloy coating of the present application, 2θ (°) diffraction peaks in the diffraction angle 2θ (°) range of 30° to 50° are all broad peaks, that is, there is no sharp peak, and the full width at half maximum values of these broad peaks can be each independently referred to the examples in the context.

In some embodiments, in the XRD pattern of the Cr—Zr—N alloy coating of the present application, there is a peak in the diffraction angle 2θ (°) range of 30° to 50°, and the full width at half maximum values of the 2θ (°) diffraction peaks in the range of 30° to 50° may be each independently ≥22°, further may be each independently ≥2.19°, more further may be each independently ≥2.2°, more further may be each independently ≥2.3°, more further may be each independently ≥3°, more further may be each independently ≥3.5°, more further may be each independently ≥4°, and more further may be each independently ≥5°.

In some embodiments, in the XRD pattern of the Cr—Zr—N alloy coating of the present application, there is only one peak in the diffraction angle 2θ (°) range of 30° to 50°, which is a broad peak.

In some embodiments, the XRD pattern of the Cr—Zr—N alloy coating is obtained by Cu target Kα radiation.

In the present application, the XRD pattern of the alloy coating can be obtained with the following instruments and methods: a German Bruker D8 Advance XRD diffractometer in a θ-2θ mode, using Cu target Kα radiation at a wavelength λ of 0.15406 nm, the X-ray tube controlled at 40 kV and 40 mA, a scanning range of 20° to 80°, and precise scanning measurement at a step size of 0.01°

A full width at half maximum value can be obtained by using conventional analysis methods in the art, including, but not limited to, the analysis software provided by the instrument supplier. For example, the method of obtaining the full width at half maximum value may include performing correction processing on the diffraction peak, which may include smoothing, background subtraction, removal of Kα2 ray, subtraction of instrument broadening, etc., and then fitting the diffraction peak with the Pseudo-Voigt function to obtain the full width at half maximum value of the diffraction peak.

The analysis software is not particularly limited. Without limitation, EDP2XRD software (version 1.0.0, copyright by Hongwei Liu, The Australian Center for Microscopy and microanalysis, the university of Sydney) can be used to process the raw data of the pattern by the following procedure: first perform a scale calibration, determine the center of the diffraction ring transmission spot, then convert the data into a pattern (with 0.00251 nm of the electron wavelength, and 0.154 nm of the X-ray wavelength, respectively), subtract the background linearly from the data and fit the corresponding diffraction peaks with the Voigt function., The FWHM values of the respective diffraction peaks are thus obtained.

The degree of atomic densely packing in alloy coatings cannot be well characterized in the conventional XRD patterns. The reason is that when detecting physical vapor deposition (PVD) films or coatings at the atomic scale (e.g., with a diameter of <3 nm), the conventional XRD technique suffers from limited resolution because the x-rays have a relatively large wavelength (>0.1 nm), thus rendering it unsuitable for PVD films or coatings with low degree of order, such as crystalline grains or amorphous bodies with a diameter of 3 nm less.

In the present application, whether the atoms constituting the coating are “sufficiently densely packed” is evaluated by selected area electron diffraction (SAED) patterns. Electron waves are chosen because their wavelengths are significantly smaller (<0.01 nm), resulting in higher resolution. In more detail, if only continuous relatively wide diffraction rings with uniform brightness appear on the SAED pattern, it indicates that the atoms in the coating are densely packed in a highly randomly mixed manner. For quantitative characterization, the SAED pattern can be converted into a characteristic interatomic spacing (d)-radial intensity profile, with the characteristic interatomic spacing as the horizontal axis and the diffraction intensity as the vertical axis. If the diffraction rings in SAED are relatively wide, then correspondingly, the FWHM in the radial intensity profile is relatively wide, reflecting that the atomic arrangement in the alloy coating is relatively densely packed.

In the present application, in terms of atomic size, the atomic radius of Cr is 1.25 Å, the atomic radius of Zr is 1.60 Å, and the atomic radius of N is 0.71 Å. The three kinds of atoms with different diameters exhibit a suitable atomic size mismatch degree and can form a sufficiently densely packed structure under conditions of high random mixing. During the growth of PVD films or alloy coatings, the atoms in the Cr—Zr—N alloy coating are sufficiently densely packed, making it easy for the alloy coating to grow densely, which can inhibit the formation and growth of columnar crystals originally caused by local ordering, and thus make it difficult to form a large number of continuous penetrating pores. Therefore, the FWHM in the radial strength profile can be used as a characteristic parameter of the sufficiently densely packed structure of the alloy coating to reflect the densely packing property of the atoms in the alloy coating. The larger the FWHM value, the better the densely packing property of the atoms in the alloy coating. In short, the present application adopts the FWHM in the radial intensity profile of SAED as the characteristic parameter of the densely packing property of the atoms, which is in line with scientific principles and has scientific validity.

When the FWHM in the radial intensity profile is greater than a certain threshold, the atoms in the coating are sufficiently densely packed. Based on a large number of experimental explorations by the inventors, in the present application, unless otherwise specified, a threshold of the FWHM in the SAED-radial intensity profile for determining whether the atoms are sufficiently densely packed is determined to be 0.21 Å, that is, it is considered that the atoms can be sufficiently densely packed when the FWHM value is ≥0.21 Å.

In the present application, transmission electron microscopy (TEM) can be used to obtain the characteristic interatomic spacing (d) radial intensity profile of an alloy coating sample.

In the present application, the radial intensity profile corresponding to the selected area electron diffraction pattern of the alloy coating can be recited as an SAED-radial intensity profile, and can also be recorded as a characteristic interatomic spacing-intensity quantitative pattern of the SAED pattern. The SAED pattern obtained using TEM can be recited as a TEM selected area electron diffraction pattern, or as a TEM-SAED pattern. The SAED-radial intensity profile obtained using TEM can also be recited as a TEM-SAED-radial intensity profile.

In the present application, conventional instruments and methods in the art may be used to obtain alloy coatings including the Cr—Zr—N alloy coating of the present application. Based on the selected area electron diffraction (SAED) pattern of the alloy coating, the corresponding radial intensity profile can be obtained, which is expressed in the form of characteristic interatomic spacing (d)-diffraction intensity, with the interatomic spacing in angstrom (Å) as the horizontal axis, and the electron diffraction intensity as the vertical axis.

In the present application, unless otherwise specified, in the radial intensity profile of the SAED pattern, if a diffraction peak has a full width at half maximum value of ≥0.21 Å, it is determined as a broad peak; and if a diffraction peak has a full width at half maximum of <0.21 Å, it is determined as a sharp peak. For a specific characteristic interatomic spacing, there may be any of three conditions: no peak, broad peak or sharp peak. In the radial intensity profile of the Cr—Zr—N alloy coating provided in the present application, the broad peak characteristics of the characteristic diffraction peaks are relatively obvious. Unless otherwise specified, in the radial intensity profile of the selected area electron diffraction pattern (SAED pattern), the “broad peak” refers to the diffraction peak with a full width at half maximum of ≥0.21 Å, and the “sharp peak” refers to the diffraction peak with a full width at half maximum of <0.21 Å.

In the present application, radial intensity profiles or SAED-radial intensity profiles can be obtained using TEM, unless otherwise specified.

In the present application, unless otherwise specified, a “broad peak” in the radial intensity profile corresponding to a SAED pattern may be defined as a peak of which full width at half maximum is ≥0.21 Å. The full width at half maximum of the broad peak may further be ≥0.25 Å, further ≥0.3 Å, more further ≥0.4 Å, more further ≥0.45 Å, more further ≥0.5 Å.

In the present application, the full width at half maximum data in the radial intensity profile corresponding to the selected area electron diffraction pattern can be obtained using the following transmission electron microscopy (TEM) method, including but not limited thereto:

TEM sample preparation: a sample is thinned with the Helios 5 CX Focused Ion Beam (FIB) workstation (Thermo Fisher, USA) to obtain an electron transparent, TEM-observable flat sample; and

SAED pattern acquisition: a Talos F200x transmission electron microscope (TEM) (Thermo Fisher, USA) is used at an electron acceleration voltage of 200 kV and a selected area diaphragm diameter of 900 nm to obtain a selected area electron diffraction (SAED) pattern of the sample; a radial intensity profile is extracted based on the selected area electron diffraction (SAED) pattern; and an FWHM value of the diffraction peak is obtained from the radial intensity profile by using the integrated FWHM assignment.

According to the principle that the full width at half maximum of the diffraction peak in the radial intensity profile corresponds to the width of the diffraction ring in the selected area electron diffraction (SAED) pattern, the selected area electron diffraction (SAED) pattern of the alloy coating can be converted into the corresponding radial intensity profile.

Those skilled in the art know that the larger the width of the diffraction ring in the SAED pattern, the stronger the random mixing degree of the atoms, and the more sufficiently densely packed the atoms are in the Cr—Zr—N alloy coating of the present application. The FWHM of the diffraction peak in the radial intensity profile is a quantitative indicator of the diffraction ring width. The larger the full width at half maximum value, the more sufficiently densely packed the atoms are.

In some embodiments, the selected area electron diffraction (SAED) pattern of the Cr—Zr—N alloy coating is obtained by using the transmission electron microscope (TEM), with an electron acceleration voltage of 200 kV and a selected area diaphragm diameter of 900 nm.

In some embodiments, in the radial intensity profile of the selected area electron diffraction pattern of the Cr—Zr—N alloy coating of the present application, there is at least one diffraction peak having a full width at half maximum of ≥0.21 Å in the range of 2.0 Å to 3.0 Å.

In the radial intensity profile of the Cr—Zr—N alloy coating provided in the present application, the full width at half maximum of the diffraction peak in the range of 2.0 Å to 3.0 Å has an upper limit value due to the densely packing limit of atoms, and a non-limiting example of the upper limit value is 3.0 Å.

In the present application, the full width at half maximum of the “broad peak” in the radial intensity profile corresponding to the SAED pattern can independently be any of, can be greater than or equal to any of, can be less than or equal to the aforementioned upper limit value (e.g., 3 Å) and greater than or equal to any of, or can each independently be selected from the intervals between any two of: 0.21 Å, 0.25 Å, 0.27 Å, 0.3 Å, 0.35 Å, 0.4 Å, 0.42 Å, 0.45 Å, 0.5 Å, 0.55 Å, 0.6 Å, 0.61 Å, 0.7 Å, 0.75 Å, 0.8 Å, 0.9 Å, 1.0 Å, 1.02 Å, 1.05 Å, 1.1 Å, 1.2 Å, 1.5 Å, 2.0 Å, 2.5 Å, etc. As a non-limiting example, the full width at half maximum of the “broad peak” in the radial intensity profile corresponding to the SAED pattern can be any one selected from following ranges: 0.21 Å to 3.0 Å, 0.21 Å to 2.0 Å, 0.21 Å to 1.5 Å, 0.21 Å to 1.1 Å, 0.21 Å to 1.05 Å, 0.21 Å to 1.02 Å, 0.25 Å to 3.0 Å, 0.25 Å to 2.0 Å, 0.25 Å to 1.5 Å, 0.25 Å to 1.1 Å, 0.25 Å to 1.05 Å, 0.3 Å to 3.0 Å, 0.3 Å to 2.0 Å, 0.3 Å to 1.5 Å, 0.3 Å to 1.1 Å, 0.3 Å to 1.05 Å, 0.3 Å to 1.02 Å, etc.

In some embodiments, in the radial intensity profile of the Cr—Zr—N alloy coating of the present application, the full width at half maximum of the diffraction peak in the range of 2.0 Å to 3.0 Å is ≤3.0 Å.

In some embodiments, in the radial intensity profile of the alloy coating of the present application, the full width at half maximum of the diffraction peaks in the range of 2.0 Å to 3.0 Å can each independently be any of, can each independently be greater than or equal to any of, or can each independently be selected from the intervals between any two of: 0.21 Å, 0.25 Å, 0.27 Å, 0.3 Å, 0.35 Å, 0.4 Å, 0.42 Å, 0.45 Å, 0.5 Å, 0.55 Å, 0.6 Å, 0.61 Å, 0.7 Å, 0.75 Å, 0.8 Å, 0.9 Å, 1.0 Å, 1.02 Å, 1.05 Å, 1.1 Å, 1.2 Å, 1.5 Å, 2.0 Å, 2.5 Å, etc. As a non-limiting example, the full width at half maximum of the diffraction peaks can be any selected from the following ranges: 0.21 Å to 3.0 Å, 0.21 Å to 2.0 Å, 0.21 Å to 1.5 Å, 0.21 Å to 1.1 Å, 0.21 Å to 1.05 Å, 0.21 Å to 1.02 Å, 0.25 Å to 3.0 Å, 0.25 Å to 2.0 Å, 0.25 Å to 1.5 Å, 0.25 Å to 1.1 Å, 0.25 Å to 1.05 Å, 0.3 Å to 3.0 Å, 0,3 Å to 2.0 |, 0.3 Å to 1.5 Å, 0.3 Å to 1.1 Å, 0.3 Å to 1.05 Å, 0.3 Å to 1.02 Å, etc.

In some embodiments, in the radial intensity profile corresponding to the selected area electron diffraction pattern of the Cr—Zr—N alloy coating of the present application, there is one broad peak in the range of 2.0 Å to 3.0 Å, the full width at half maximum value of which can be referred to the examples in the context. Taking the full width at half maximum of the broad peak ≥0.35 Å as an example, at least one diffraction peak in the range of 2.0 Å to 3.0 Å satisfies ≥0.35 Å in a radial intensity profile corresponding to a selected area electron diffraction pattern.

In some embodiments, in the radial intensity profile corresponding to the selected area electron diffraction pattern of the Cr—Zr—N alloy coating of the present application, there are two or more broad peaks in the range of 2.0 Å to 3.0 Å, the full width at half maximum values of which can be referred to the examples in the context.

In some embodiments, in the radial intensity profile corresponding to the selected area electron diffraction pattern of the Cr—Zr—N alloy coating of the present application, diffraction peaks in the range of 2.0 Å to 3.0 Å are all broad peaks, the full width at half maximum values of all diffraction peaks are ≥0.21 Å and can also be referred to the definitions in the context.

In some embodiments, the characteristic interatomic spacing of the Cr—Zr—N alloy coating of the present application is obtained by using TEM diffraction data; wherein, the TEM characterization of the alloy coating is performed with an electron acceleration voltage of 200 kilovolts and a selected area diaphragm diameter of 900 nanometers.

In some embodiments, the TEM characterization is performed with an electron acceleration voltage of 200 kV and a selected area diaphragm diameter of 900 nm to obtain a selected area electron diffraction (SAED) pattern of the Cr—Zr—N alloy coating.

In some embodiments, based on any of the aforementioned suitable embodiments, the Cr—Zr—N alloy coating has a thickness of dₘᵢₙ to 6 μm, wherein dₘᵢₙ can be selected from 10 nm to 50 nm, or can also be any of, or can be selected from intervals between any two of: 10 nm, 20 nm, 25 nm, 30 nm, 40 nm, 50 nm, etc. For example, the thickness of the Cr—Zr—N alloy coating can be 25 nm to 6 μm, 30 nm to 6 μm, 40 nm to 6 μm, 50 nm to 6 μm, 1.0 μm to 2.5 μm, 1.0 μm to 2.0 μm, etc. The size unit μm refers to “micrometer” and “nm” refers to “nanometer”.

By controlling the Cr—Zr—N alloy coating to have a relatively appropriate thickness, the corrosion resistance and/or high hardness of the alloy coating can be more fully functioned. The thicker the Cr—Zr—N alloy coating is, the more beneficial it is to improve the corrosion resistance and/or hardness of the alloy coating.

The Cr—Zr—N alloy coating provided in the present application can not only provide excellent corrosion resistance, but also has high hardness, thereby better reducing the occurrence of scratches or weakening scratch damage. Further, the Cr—Zr—N alloy coating provided in the present application can have both high corrosion resistance and high hardness at a relatively low thickness, thereby saving raw materials, simplifying the process, shortening the production cycle, and significantly reducing costs. Compared with conventional alloy coatings, the Cr—Zr—N alloy coating of the present application can provide a denser structure and can achieve better corrosion resistance and high hardness at the same thickness, thereby reducing the coating thickness while maintaining better coating protection properties. This is beneficial for saving raw materials, simplifying processes, shortening production cycles, and significantly reducing costs.

In some embodiments, the thickness of the Cr—Zr—N alloy coating is 10 nm to 6 μm.

In some embodiments, the thickness of the Cr—Zr—N alloy coating is 25 nm to 6 μm.

In some embodiments, the thickness of the Cr—Zr—N alloy coating is 1 μm to 2.5 μm.

In addition, when a relatively thin Cr—Zr—N alloy coating of the present application is formed on a substrate, the formed alloy film product can present a silvery white metallic color, which is close to the metallic color of the substrate, thereby achieving a beautiful decorative effect without changing the color of the substrate.

In a third aspect of the present application, an alloy film product is provided. The alloy film product includes a substrate 100 and the Cr—Zr—N alloy coating as described in the second aspect of the present application (i.e., Cr—Zr—N alloy coating 300 as shown in FIG. 1). The Cr—Zr—N alloy coating is disposed on at least one side of the substrate.

The alloy film product provided in the present application includes a film layer formed by the Cr—Zr—N alloy coating of the present application, and therefore is referred to as an alloy film product.

The Cr—Zr—N alloy coating provided in the present application can be used as a surface layer of the alloy film product and has both beautiful decorative effect and protection effect. The Cr—Zr—N alloy coating provided in the present application can also be located between the substrate and a surface layer to provide excellent protection effect, thereby better resisting corrosion and scratches.

The Cr—Zr—N alloy coating provided in the present application may be disposed on one side or both sides of the substrate.

In some embodiments, a surface material of the substrate is one of an alloy, an elemental metal, or a non-metallic inorganic material. Without limitation, the alloy may have a material type including one or more of nickel-based, iron-based, tungsten-based, titanium-based, silicon-based, aluminum-based, copper-based, cobalt-based, zirconium-based, and zinc-based materials. Without limitation, the elemental metal may be any one of zinc, gold, platinum, zirconium, hafnium, niobium, tantalum, nickel, copper, aluminum, iron, silver, and chromium. Without limitation, the non-metallic inorganic material may include one or both of ceramic and glass. Without limitation, the non-metallic inorganic material may include a silicon wafer

The Cr—Zr—N alloy coating provided in the present application can be applied to a variety of substrates. The substrates are made of materials including, but being not limited to an alloy, an elemental metal, a non-metallic inorganic material (e.g., silicon wafers, ceramics, glass), and other materials.

In some embodiments, the surface material of the substrate is one of light alloys or one of stainless steels. Optionally, the light alloy may include one or more selected from titanium alloy, aluminum alloy, and magnesium alloy.

In some embodiments, the surface of the substrate is made of one of light alloys. Further, the light alloy may include one or more selected from titanium alloy, aluminum alloy, and magnesium alloy.

In some embodiments, the surface material of the substrate is one of stainless steels. Furthermore, the stainless steel alloy may be any one of austenitic stainless steel, ferritic stainless steel, martensitic stainless steel, and the like.

In some embodiments, the alloy film product satisfies one or more of the following characteristics:
the Cr—Zr—N alloy coating and the substrate are in direct contact with each other (in this case, there is no transition layer), or a transition layer is provided between the Cr—Zr—N alloy coating and the substrate; further, the transition layer may be a single-layer structure or a multi-layer structure (that is, one or more structural layers may be formed between the Cr—Zr—N alloy coating provided in the present application and the substrate);
the Cr—Zr—N alloy coating is disposed on a surface of the alloy film product, or a surface layer is provided on one side of the Cr—Zr—N alloy coating away from the substrate; further, the surface layer can be a single-layer structure or a multi-layer structure (that is, one or more structural layers can be subsequentially formed on the Cr—Zr—N alloy coating provided in the present application).

In the present application, unless otherwise specified, “transition layer” and “transition film layer” have the same meaning and can be used interchangeably. They both refer to a structural layer having transitional properties and located between the substrate and the Cr—Zr—N alloy coating of the present application in the alloy film product, which can be a single-layer structure or a multi-layer structure.

In the present application, unless otherwise specified, “surface layer” and “surface film layer” have the same meaning and can be used interchangeably. They both refer to a structural layer disposed on one side of the Cr—Zr—N alloy coating of the present application away from the substrate in the alloy film product and on the surface of the product, which can be a single-layer structure or a multi-layer structure.

In some embodiments, the Cr—Zr—N alloy coating 300 is in direct contact with the substrate 100. In this case, there is no transition layer.

In some embodiments, a transition layer 200 is provided between the Cr—Zr—N alloy coating 300 and the substrate 100.

In some embodiments, the Cr—Zr—N alloy coating 300 is disposed on the surface of the alloy film product.

In some embodiments, a surface layer 400 is further provided on one side of the Cr—Zr—N alloy coating 300 away from the substrate 100.

FIG. 1 provides a schematic structural diagram of an exemplary alloy film product including a Cr—Zr—N alloy coating of the present application in an embodiment of the present application, which includes a substrate 100 and a Cr—Zr—N alloy coating 300.

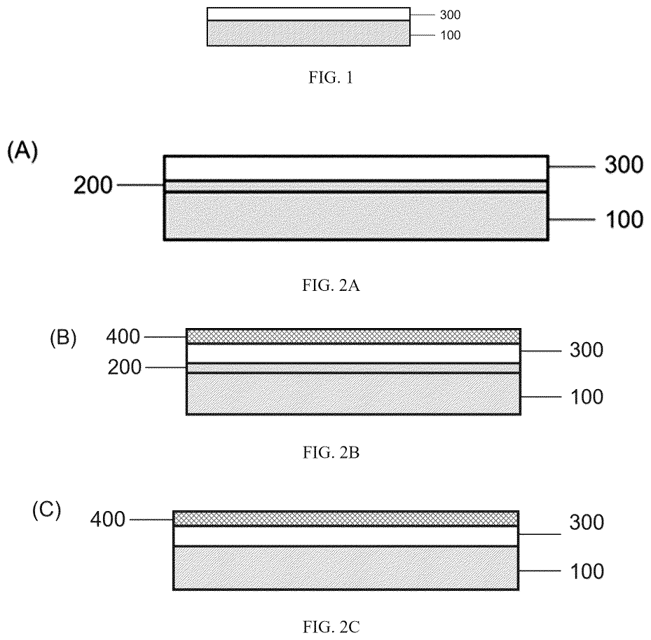

FIG. 2 provides schematic structural diagrams of alloy film products in some embodiments of the present application: (A) including a substrate 100, a transition layer 200 and a Cr—Zr—N alloy coating 300; (B) including a substrate 100, a transition layer 200, a Cr—Zr—N alloy coating 300 and a surface layer 400; (C) including a substrate 100, a Cr—Zr—N alloy coating 300 and a surface layer 400.

When the Cr—Zr—N alloy coating provided in the present application is arranged in the protective coating of the alloy film product, the Cr—Zr—N alloy coating can be flexibly arranged in various positions. It can be provided as a single structural layer of the protective coating, or as one layer of a multi-layer structural protective coating. For example, the Cr—Zr—N alloy coating can be used for surface protection, in this case the Cr—Zr—N alloy coating is disposed on a surface of the alloy film product and can be used for providing a high-brightness surface for the alloy film product. The Cr—Zr—N alloy coating can also be used as an intermediate protective layer, in this case another structural layer is provided on the outside of the Cr—Zr—N alloy coating, that is, the Cr—Zr—N alloy coating may not serve as a surface layer. Different coating position arrangements can all achieve relatively good scratch resistance and relatively good corrosion resistance.

In some embodiments, the alloy film product is one of a 3C digital product, an automotive product, an aerospace product, a wearable product, and a sport product.

Without limitation, the 3C digital product may include, but is not limited to, mobile device components, wearable components, vehicle-mounted components, etc.

Depending on the difference in the main component of the substrate, the alloy film product can be any one of a light alloy product, a stainless steel product, an elemental metal product, a non-metal-based inorganic product (such as a ceramic-based product, a silicon-based product, a glass-based product), etc., which means that the main component of the substrate is a light alloy, stainless steel, an elemental metal, etc. Without limitation, the light alloy product may include, but is not limited to, an aluminum alloy product, a titanium alloy product, a magnesium alloy product, etc. Without limitation, the stainless steel product may include, but is not limited to, austenitic stainless steel, ferritic stainless steel, and martensitic stainless steel. Without limitation, the elemental metal product may include, but is not limited to, zinc, gold, platinum, zirconium, hafnium, niobium, tantalum, nickel, copper, aluminum, iron, silver, and chromium, further such as copper, aluminum, iron, silver, and chromium.

In one of the embodiments, the alloy film product is an aluminum alloy product.

In one of the embodiments, the alloy film product is a stainless steel product.

In one of the embodiments, the alloy film product is a non-metal-based inorganic product, and may be a silicon-based product, a ceramic-based product, or a glass-based product.

In one of the embodiments, the alloy film product is a copper product.

The alloy film product can be an intermediate product or a final product. The final product can be used directly or sold. The Intermediate product can be further processed or assembled with other components into new products.

In a fourth aspect of the present application, there is provided an application of the Cr—Zr—N alloy material as described in the first aspect or an application of the Cr—Zr—N alloy coating as described in the second aspect.

As mentioned above, the Cr—Zr—N alloy coating of the present application can serve as a surface layer or can be located between the substrate and a surface layer, In some embodiments, there is provided an application of the Cr—Zr—N alloy material as described in the first aspect of the present application in preparing a high-brightness surface coating or an application of the Cr—Zr—N alloy coating as described in the second aspect of the present application as a high-brightness surface coating. Further, the high-brightness surface coating has a brightness value L of ≥70 as determined by Lab method. In some of the embodiments, the high-brightness surface coating is also a corrosion-resistant protective coating.

In the present application, unless otherwise specified, “surface coating” refers to a coating disposed on the surface of the product. The surface coating may be the Cr—Zr—N alloy coating of the present application or be provided with an additional surface layer in addition to the Cr—Zr—N alloy coating of the present application.

When the Cr—Zr—N alloy coating is disposed on the surface of the product, it can not only give the product a high-brightness surface, but also provide excellent corrosion resistance.

The L values of the Cr—Zr—N alloy coatings of the present application can be ≥70, and some of them can be up to 81, with presenting a high-brightness silver-white color, which are much higher than the L values of the conventional alloy coatings approximately ranging from 55 to 65.

In some embodiments, the brightness value L is ≥70, further ≥75, and further ≥80, as determined by the Lab method.

In some embodiments, taking an aluminum alloy substrate as an example, a corrosion-resistant protective coating including the Cr—Zr—N alloy coating of the present application is formed on a surface of the aluminum alloy substrate. By using the ASTM B117 salt spray test method, the corrosion-resistant protective coating has a protection time of ≥24 hours (that is, can pass the 24-hour test) and can pass the 48-hour test for most embodiments in a salt spray corrosion test. Further, a more detailed test method described above or below can be used. Taking an aluminum alloy substrate as an example, the protection time of the conventional alloy coating in a salt spray corrosion test is generally difficult to reach 8 hours under the same test conditions.

The Cr—Zr—N alloy coating provided in the present application can have both excellent corrosion resistance and high hardness at a relatively low thickness, thereby saving raw materials, simplifying the process, shortening the production cycle, and significantly reducing costs. When the alloy coating is thin, the formed alloy film product can present a silvery white metallic color, which is close to the metallic color of the substrate and is more conducive to achieving a beautiful decorative effect without changing the color of the substrate.

In a fifth aspect of the present application, a method for preparing an alloy coating is provided, including the following steps: depositing constituent elements of the Cr—Zr—N alloy coating in a predetermined atomic ratio on at least a portion of a surface of a substrate through vapor deposition technique to form the Cr—Zr—N alloy coating as described in the second aspect of the present application.

The method for preparing the Cr—Zr—N alloy coating provided in the present application is simple, easy to operate, green and environmentally friendly, and has the advantages of being quantifiable, highly efficient, and repeatable, and thus is suitable for industrial applications.

The definition of the substrate can be found in the third aspect of the present application.

In some embodiments, the vapor deposition technique is a physical vapor deposition technique. Furthermore, the physical vapor deposition can be implemented by one or more selected from vacuum evaporated deposition, sputtering coating, arc plasma plating, ion plating and molecular beam epitaxy.

In one of the embodiments, the physical vapor deposition is implemented by magnetron sputtering coating.

In some embodiments, the constituent elements of the Cr—Zr—N alloy coating are deposited on at least a portion of the surface of the substrate in a predetermined atomic ratio through sputtering coating such as magnetron sputtering coating.

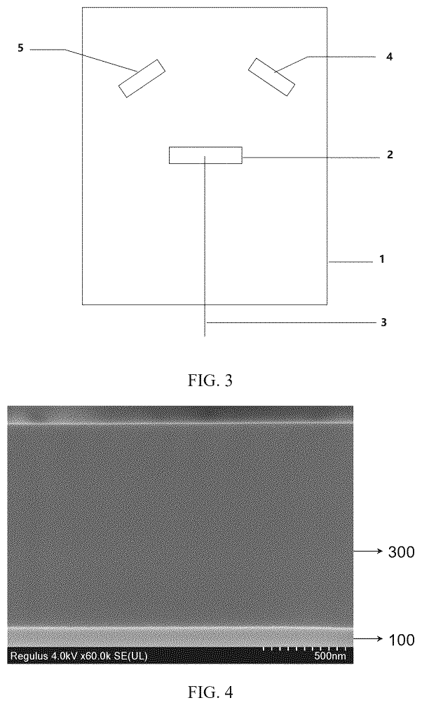

In some embodiments, reference may be made to the device as shown in FIG. 3. The device as shown in FIG. 3 includes a vacuum chamber 1, a sample stage 2, electrical circuit connecting the sample stage to a direct-current power supply 3, a chromium target 4, and a zirconium target 5. The chromium target 4 is a chromium target driven by a direct-current power supply assisted by a radio-frequency power supply, and the zirconium target 5 is a zirconium target driven by a direct-current power supply assisted by a radio-frequency power supply. This drawing is not drawn at a 1:1 scale. The relative sizes of the components are drawn in the drawings only as examples to facilitate understanding of the present application but are not necessarily drawn according to the actual scale. The scale in the drawings does not constitute a limitation to the present application. The Cr—Zr—N alloy coating of the present application can be formed by reactive sputtering with N₂-containing gas (such as an Ar/N₂ mixed gas) in the vacuum chamber 1.

In some embodiments, the method for preparing the Cr—Zr—N alloy coating includes the following step: sputter deposition of constituent elements of the Cr—Zr—N alloy coating on at least a portion of the surface of the substrate by using one or more target materials including chromium and zirconium under introducing a mixed gas including argon gas and nitrogen-containing gas to form the Cr—Zr—N alloy coating. The nitrogen-containing gas may be, but is not limited to, the nitrogen gas. In this case, a gas volume ratio of argon gas to nitrogen gas in the mixed gas may be 2:1 to 6:1 such as 2:1, 3:1, 4:1, 5:1, 6:1, etc. By selecting nitrogen gas as the nitrogen-containing gas and controlling the nitrogen gas concentration to a certain level, the performance of the Cr—Zr—N alloy coating of the present application can be further adjusted.

The target material may include one or more of a chromium target, a zirconium target, and an alloy target. The alloy target includes at least two kinds of metallic elements in the Cr—Zr—N alloy coating. The atomic ratio of the metallic elements in the alloy target can be equal to or close to the atomic ratio of the corresponding metallic elements in the Cr—Zr—N alloy coating. In some embodiments, the alloy target is a chromium-zirconium-based alloy target, and the chromium-zirconium-based alloy target includes at least chromium and zirconium, such as a CrZr alloy target, a CrZrN alloy target, and the like. In some embodiments, the atomic ratio of Cr to Zr in the chromium-zirconium-based alloy target is 65%:35%. In some embodiments, the alloy target includes all metallic elements in the Cr—Zr—N alloy coating. Examples of the alloy target can be found in Example 2 below.

In the present application, unless otherwise specified, “chromium-zirconium-based alloy target” includes at least chromium and zirconium and may or may not include other elements. When other elements are included, it is understood that the chemical composition of the target material should generally be within the range of the predetermined chemical formula (CrₓZr_{y}N_{z})Mₐ. For example, the chromium-zirconium-based alloy target may be a chromium-zirconium-nitrogen alloy target (i.e., a CrZrN alloy target) consisting of three elements of chromium, zirconium, and nitrogen.

In some embodiments, a chromium-zirconium alloy target is used to replace the chromium target 4 in FIG. 3 and installed at the location of the original chromium target 4 in FIG. 3.

In some embodiments, taking the sputtering coating, for example, magnetron sputtering coating as an example, the method for preparing the Cr—Zr—N alloy coating includes the following step: sputter deposition of constituent elements of the Cr—Zr—N alloy coating on at least a portion of the surface of the substrate by using a chromium target and a zirconium target, or using a chromium-zirconium alloy target (i.e., a CrZr alloy target) under introducing a mixed gas including argon gas and nitrogen-containing gas, to form the Cr—Zr—N alloy coating.

In some embodiments, before the step of “sputter deposition of constituent elements of the Cr—Zr—N alloy coating on at least a portion of the surface of the substrate”, the method further includes the following step: cleaning the substrate. Cleaning the substrate may be performed with a conventional cleaning method in the technical field including but not limited to the field of decorative plating.

In some embodiments, cleaning the substrate includes the following steps: placing the substrate in water, ultrasonic cleaning for 10 min to 15 min, vacuum drying the cleaned substrate for 15 min to 20 min, and placing the dried substrate on a sample stage of a sputtering coating (such as magnetron sputtering coating) device. The sample stage may be a rotatable sample stage.

In one of the embodiments, cleaning the substrate includes the following steps: placing the substrate in deionized water (i.e., DI water), ultrasonic cleaning for 10 min to 15 min, placing the cleaned substrate in a vacuum oven and drying for 15 min to 20 min, and placing the dried substrate on a rotatable sample stage in a vacuum chamber.

In some embodiments, after the step of “cleaning the substrate” and before the step of “sputter deposition of constituent elements of the Cr—Zr—N alloy coating on at least a portion of the surface of the substrate”, the method further includes the following step: forming a transition layer (which can serve as a buffer film) on at least a portion of the surface of the cleaned substrate. For example, constituent elements of the transition layer can be deposited on at least a portion of the surface of the cleaned substrate.

In some embodiments, after the Cr—Zr—N alloy coating of the present application is formed on one side of the substrate, a surface layer which may be a single-layer structure or a multi-layer structure, can be subsequentially formed by deposition.

In some embodiments, the sputter deposition is performed at a temperature of 30 °C to 330 °C, for example, 30 °C, 40 °C, 50 °C, 60 °C, 70 °C, 80 °C, 90 °C, 100 °C, 150 °C, 200 °C, 250 °C, 300 °C, 330 °C, etc.

In some embodiments, the mixed gas including argon gas and nitrogen-containing gas has a total gas pressure of 0.3 Pa to 1.2 Pa, for example, 0.3 Pa, 0.5 Pa, 0.8 Pa, 1 Pa, 1.2 Pa, etc. The pressure unit Pa is abbreviated for “Pascal”.

In some embodiments, the sputter deposition is performed by radio frequency assisted direct-current sputtering, such that the performance of the alloy coating formed by sputter deposition can be further improved when compared with other preparation methods.

In some embodiments, the target material includes a chromium target. The power density of chromium target is 3.5 W/cm² to 6.7W/cm². The unit W/cm² is abbreviated for “watt per square centimeter”.

In some embodiments, the target material includes a zirconium target. The power density of zirconium target is 0.5 W/cm² to 3.0 W/cm².

In some embodiments, the target material includes a chromium target and a zirconium target. A power density of the chromium target is 3.5 W/cm² to 6.7 W/cm², and a power density of zirconium target is 0.5 W/cm² to 3.0 W/cm².

In some embodiments, the target material includes an alloy target, and the alloy target includes at least two kinds of metallic elements in the Cr—Zr—N alloy coating; optionally, the target material includes a chromium-zirconium-based alloy target which has a power density of 4 W/cm² to 6 W/cm².

In some embodiments, the target material includes a chromium-zirconium alloy target, a power density of which is 5 W/cm².

In some embodiments, the target material is a chromium-zirconium alloy target, a power density of which is 4 W/cm² to 6 W/cm², optionally 5 W/cm².

In some embodiments, a bias voltage for the substrate is −150 V to −20 V, such as −150 V, −120 V, −100 V, −90 V, −80 V, −60 V, −50 V, −40 V, −30 V, −20 V, etc. Unit V is abbreviated for “volt”.

In some embodiments, a gas flow rate of the nitrogen-containing gas may be 5 sccm to 52 sccm, for example, 5 sccm, 10 sccm, 20 sccm, 25 sccm, 30 sccm, 40 sccm, 50 sccm, 52 sccm, etc. Furthermore, the nitrogen-containing gas is nitrogen gas. The unit sccm, abbreviated for standard cubic centimeter per minute, is a flow rate unit and used to characterize the gas flow rate.

In some embodiments, the sputter deposition is performed for 10 min to 150 min, for example, 10 min, 15 min, 30 min, 45 min, 60 min, 90 min, 100 min, 120 min, etc. The thickness of the Cr—Zr—N alloy coating of the present application can be controlled by adjusting the deposition time. As the deposition time increases, the thickness of the Cr—Zr—N alloy coating increases.

In some embodiments, the background vacuum degree of the vacuum chamber is ≤5.0×10⁻⁴ Pa. This pressure setting can ensure the collision between sputtered particles and gas molecules and can reduce the entry of impurities into gas molecules in the deposition process, so as to improve the corrosion resistance, purity and bonding strength of the Cr—Zr—N alloy coating of the present application.

It can be understood that argon gas and nitrogen-containing gas can be introduced into the vacuum chamber through a single path, or into the vacuum chamber after mixed through a mixing cylinder, thereby reducing the impurity concentration of the Cr—Zr—N alloy coating of the present application, and improving performance thereof.

In some embodiments, “the constituent elements of the Cr—Zr—N alloy coating are deposited on at least a portion of the surface of the substrate in a predetermined atomic ratio through sputtering coating such as magnetron sputtering coating” is performed by following steps: introducing a mixed gas containing argon gas and nitrogen-containing gas into the vacuum chamber 1, maintaining the pressure in the vacuum chamber 1 at 0.5 Pa to 0.8 Pa, initiating a bias voltage and setting the bias voltage to −150 V to −20 V, setting the power density of the chromium target 4 to 3.5 W/cm² to 6.7 W/cm², setting the power density of the zirconium target 5 to 0.5 W/cm² to 3.0W/cm², and depositing a Cr—Zr—N alloy coating on at least a portion of the surface of the cleaned substrate. Further, by controlling the film forming time, the Cr—Zr—N alloy coating with different thicknesses can be obtained.

Some Examples are provided below.

The embodiments of the present application will be described in detail below with reference to examples. These embodiments are only used to illustrate the present application but not to limit the scope of the present application. Experimental methods in the following examples where the conditions are not specified are preferentially referred to the instructions given in the present application, or may be referred to the experimental manuals or conventional conditions in the art, or may be referred to the conditions recommended by the manufacturer, or may be referred to experimental methods known in the art.

In the following examples, the measurement parameters of the raw material components may have slight deviations in the range of weighing accuracy, unless otherwise specified. Regarding temperature and time parameters, acceptable deviations due to instrument test accuracy or operating accuracy are also allowed to be present.

### Test Methods

### 1. Chroma Value Test of Alloy Coating

When the chroma value of the alloy coating was tested, substrates made from the same material as used in actual applications were used for samples. The degree of improvement of the alloy coating on the compactness and other properties of the substrate was tested. The “substrates made from the same material as used in actual applications” may be made of a material including, but being not limited to, aluminum alloy, stainless steel.

L, a, and b values of a sample can be tested using a CM-3700A-U desktop spectrophotometer (Konica, Japan), with F2 light source used as a light receiving system. Each sample was tested for 6 matrix points, and an average value was calculated.

Among them, L value represents the brightness value, a value represents the red or green chroma values, and b value represents the yellow or blue chroma values. The a value reflects the red or green color of an object, a positive value represents the red chroma value, and a negative value represents the green chroma value. The b value reflects the yellow or blue color of an object, a positive value represents the yellow chroma value, and a negative value represents the blue chroma value.

A larger L value indicates a higher brightness, suggesting a denser coating surface. The mechanism is as follows: in the spectrophotometer, an incident light hits the surface of the sample to be tested, to form a reflection, and thus obtain a reflectance curve. The amplitude of the curve can reflect the density of the material, which can be characterized by the L value. For the same material, the higher the density, the larger the L value it displays.

### 2. Morphological Observation and Compositional Analysis of Alloy Coating

A silicon wafer was used as the substrate for all samples to be tested.

### Scanning Electron Microscopy (SEM) and Energy Dispersive X-ray Spectroscopy (EDX)

Morphological observation: A scanning electron microscope (Regulus 8230, manufactured by Hitachi) was used;

Compositional analysis: An energy dispersive x-ray spectrometer attached to the scanning electron microscope (Regulus 8230, manufactured by Hitachi) was used, and relative intensities of all elements were corrected by the ZAF method; and Test parameters: 15 kilovolts (kV) of electron acceleration voltage, 10 microamperes (μA) of beam current, and 200 times sample magnification. Each sample was tested for 10 points, and an average value was calculated.

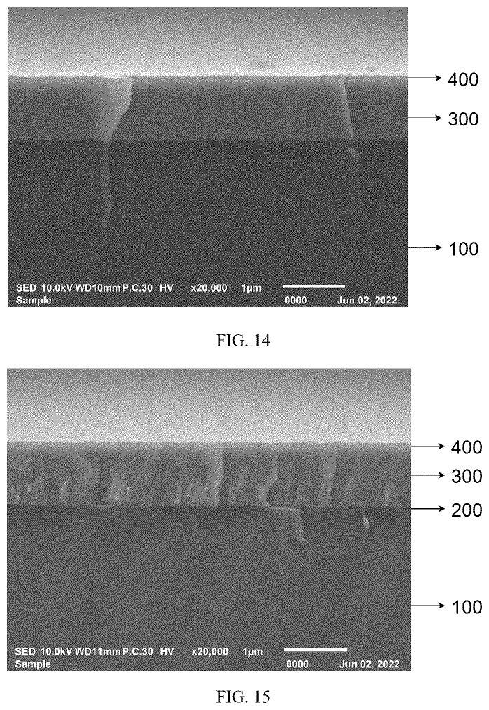

In some SEM images, when preparing cross-sectional samples for characterizing, some cross-sectional delamination occurred due to brittle fracture of the silicon wafer, but did not affect the observation and analysis of cross-sectional morphology. The positions of different structural layers in the substrate and the protective coating can be determined according to the thickness of the corresponding structural layers. The structural layer positions marked in FIGS. 14 and 15 can be referred to.

### 3. X-Ray Diffraction (XRD) Characterization of Alloy Coating

When alloy coatings were characterized by XRD, silicon wafers were used as substrates.

In the XRD pattern, the horizontal axis represents 2θ in degrees, and the vertical axis represents X-ray diffraction intensity in arbitrary unit (a.u.). The corresponding radial intensity profile extracted based on the selected area electron diffraction (SAED) pattern of the alloy coating is expressed in the form of characteristic interatomic spacing (d)-diffraction intensity, with the interatomic spacing in angstrom (Å) as the horizontal axis, and the electron diffraction intensity in a.u. as the vertical axis.

In the XRD pattern and the radial intensity profile corresponding to the SAED pattern, a.u. has a well-known meaning in the art.

### 3.1. Calculation of Full Width at Half Maximum Values of Diffraction Peaks in XRD Pattern

A Bruker D8 ADVANCE XRD diffractometer from German was used in the 0-20 mode, using Cu target Kα radiation at a wavelength λ of 0.15406 nm with an x-ray tube operated at 40 kV and 40 mA, and precise scanning measurements at a step size of 0.01° within a scanning range of 20° to 80°.

The method of obtaining the full width at half maximum value includes performing correction processing on the diffraction peak, which includes smoothing, background subtraction, removal of Kα2 ray, subtraction of instrument broadening, etc., and then fitting the diffraction peak with the Pseudo-Voigt function to obtain the full width at half maximum value of the diffraction peak.

EDP2XRD software (version 1.0.0, copyright by Hongwei Liu, The Australian Center for Microscopy and Microanalysis, the university of Sydney) was used to process the raw data of the pattern by the following procedure: first perform a scale calibration, determine the center of the diffraction ring transmission spot, then convert the data into a pattern (with 0.00251 nm of the electron wavelength and 0.154 nm of the x-ray wavelength, respectively); subtract the background linearly from the data and fit the diffraction peaks with the Voigt function. The FWHM values of the respective diffraction peaks are thus obtained.:

### 3.2. Determination of Formation of Broad Peak in XRD Pattern of Alloy Coating

Whether there is a broad peak in the diffraction angle 2θ (°) range of 30° to 50° in the XRD pattern was determined as follows. In the XRD pattern, if the full width at half maximum value of the 2θ (°) diffraction peak was ≥2°, the peak was identified as a “broad peak”; if the full width at half maximum value of the 2θ (°) diffraction peak was <2°, the peak was identified as a sharp peak.

For a given 20θ (°) position, there may be any of three conditions: no peak, sharp peak or broad peak.

### 4. TEM Characterization

When alloy coatings were characterized by TEM, silicon wafers were used as substrates.

### 4.1. Full Width at Half Maximum Data of the Diffraction Rings in the TEM Diffraction Pattern was Obtained by the Following Method:

TEM sample preparation: a sample was thinned with the Helios 5 CX focused ion beam (FIB) workstation (Thermo Fisher, USA) to obtain an electron transparent, TEM-observable flat sample;

SAED pattern acquisition: a Talos F200x transmission electron microscope (TEM) (Thermo Fisher, USA) was used at an electron acceleration voltage of 200 kV and a selected area diaphragm diameter of 900 nm to obtain a selected area electron diffraction (SAED) pattern of the sample.

Radial intensity profile was extracted by using EDP2XRD software (version 1.0.0, copyright by Hongwei Liu, The Australian Center for Microscopy and Microanalysis, The university of Sydney) to process the raw data of the pattern by the following procedure: first perform a scale calibration, determine the center of the diffraction ring transmission spot, then convert the data into a radial intensity profile (in which the electron wavelength is 0.00251 nanometers, and the x-ray wavelength is 0.154 nanometers), with the characteristic interatomic spacing as the horizontal axis, and the diffraction intensity as the vertical axis.

The FWHM value was obtained by deducting the linear background from the diffraction peak, and then fitting with the Voigt function to obtain the FWHM values of the respective diffraction peaks.

4.2. Whether there is a broad peak in the range of 2.0 Å to 3.0 Å in the radial intensity profile of the selected area electron diffraction pattern was determined as follows: If the FWHM value of the diffraction peak corresponding to the characteristic interatomic spacing was 20.21 Å, the diffraction peak was identified as a broad peak, if the FWHM value of the diffraction peak corresponding to the characteristic interatomic spacing was <0.21 Å, the diffraction peak was identified as a sharp peak. For a specific characteristic interatomic spacing, there may be any of three conditions: no peak, sharp peak, or broad peak.

### 5. Corrosion Resistance Evaluation of Alloy Coatings by Salt Spray Test

When evaluating the corrosion resistance of the alloy coatings by salt spray test, substrates made from the same material as used in actual applications were used for samples. The degree to which the corrosion resistance of the substrate was improved by the alloy coating was tested. The “substrate made from the same material as used in actual applications” may be made of a material including, but being not limited to, aluminum alloy, stainless steel.

The standard for ASTM B117 salt spray test method was that: a solution with a chemical composition of sodium chloride (NaCl), deionized water and sodium hydroxide (NaOH), and a pH value of 6.5 to 7.2.

12 hours can be used as a sub-cycle of the corrosion resistance evaluation by salt spray test.

For the alloy coatings which are deposited on various substrates made of different materials, the test cycles thereof can be different, for example:
the test cycle for a sample containing an aluminum alloy substrate was 48 h or 24 h;
the test cycle for a sample containing a stainless steel substrate was 144 h or 96 h; and
the test cycle for a sample containing a copper sheet substrate was 12 h.

The standard for “passed (OK)” in the corrosion resistance evaluation by salt spray test was that: the sample after testing appeared no corrosion, no discoloration, and no rust.

The standard for “failed (NG)” in the corrosion resistance evaluation by salt spray test was that: the sample after testing appeared corrosion, discoloration or rust.

### 6. Hardness Test of Alloy Coating

When the hardness of the alloy coating was tested, substrates made from the same material as used in actual applications were used for samples.

The “substrate made from the same material as used in actual applications” may be made of, but is not limited to, aluminum alloys, stainless steels, or copper sheets.

In the following Examples, unless otherwise specified, when the hardness of the alloy coating was tested, aluminum alloy or stainless steel was used as the substrate. The alloy coating was deposited on the aluminum alloy or stainless steel according to predetermined preparation parameters to obtain a test sample which was used for testing the hardness of the alloy coating. This is mainly due to the following considerations: a strong pressure will be generated when a probe penetrates the test sample during the nanoindentation test, such that the substrate is required to have a certain toughness. If a brittle silicon wafer is used, cracks may occur during the test, resulting in inaccurate test results. Alloy materials are more suitable as the substrate to be tested in the nanoindentation test due to their excellent toughness. Meanwhile, using alloy materials as the substrate to measure nano-hardness is universal in the coating field for the characterization of nano-hardness parameters.

The hardness of each film or each coating was tested using a nanoindenter model NHT3 (Anton-Paar, Austria), which was equipped with a tetrahedral Berkvich indenter with the indentation depth set to 100 nm. The load was changed with the indentation depth. Each sample was tested for 5 matrix points, and an average value was calculated.

In the following Examples, DI water refers to deionized water.

The stainless steel sheets, aluminum alloy sheets, and silicon wafers in the following Examples and Comparative Examples each were made of the same material.

In the following Examples, the target material was sputtered by radio frequency assisted direct current sputtering.

In the following Examples, in the XRD pattern and the SAED-radial intensity profile, the phrase “there is only one broad peak” means that there is only one characteristic peak that is a broad peak, unless otherwise specified.

### Example 1

In this Example, the chemical composition of the Cr—Zr—N alloy coating was Cr_{81.6}Zr_{13.7}N_{4.7}.

Pretreatment of substrate: Samples including a stainless steel sheet, an aluminum alloy sheet, and a silicon wafer each with a dimension of 50 mm×50 mm, were ultrasonically cleaned in deionized water for 15 min, dried in an oven, and placed in a vacuum chamber of a coating machine. The vacuum chamber was evacuated to 5×10⁻⁴ Pa, heated to 150 °C, and kept at a constant temperature for 15 min. The unit of size, “mm”, refers to “millimeter”.

Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.

Deposition of the alloy coating: A rotating stand of the sample stage was turned on with the speed set to 6 revolutions per minute. The distance from the sample stage to the target surface was adjusted to 8 centimeters (cm). Cr target and Zr target were electrified with a radio frequency assisted direct-current power supply. Ar gas and N₂ gas were introduced, with the N₂ gas flow rate set to 5 sccm and the Ar:N₂ gas volume ratio set to 6:1. The furnace pressure was maintained at 0.6 Pa. The bias voltage was initiated and set to −100 V. The power density of the Cr target was set to 6 W/cm², and the power density of the Zr target was set to 1.5 W/cm². A Cr—Zr—N alloy coating was deposited, and the film formation time was controlled to obtain a resulting film thickness of 1300 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis, XRD analysis and TEM characterization.

The compositional analysis showed that the alloy coating on the surface of the substrate was composed of Cr_{81.6}Zr_{13.7}N_{4.7}.

Chroma value test results were L: 81.31, a: 0.26, b: 2.88 for the aluminum alloy substrate sample, and L: 82.30, a: 0.20, b: 2.45 for the stainless steel substrate sample. The samples showed a silvery white color.

In the corrosion resistance evaluation by salt spray test, the aluminum alloy substrate sample can pass the 48-h test, and the stainless steel substrate sample can pass the 144-h test, showing excellent protection properties.

The hardness values of the aluminum alloy substrate sample and the stainless steel substrate sample were tested to be 13.7 GPa and 14.6 GPa, respectively.

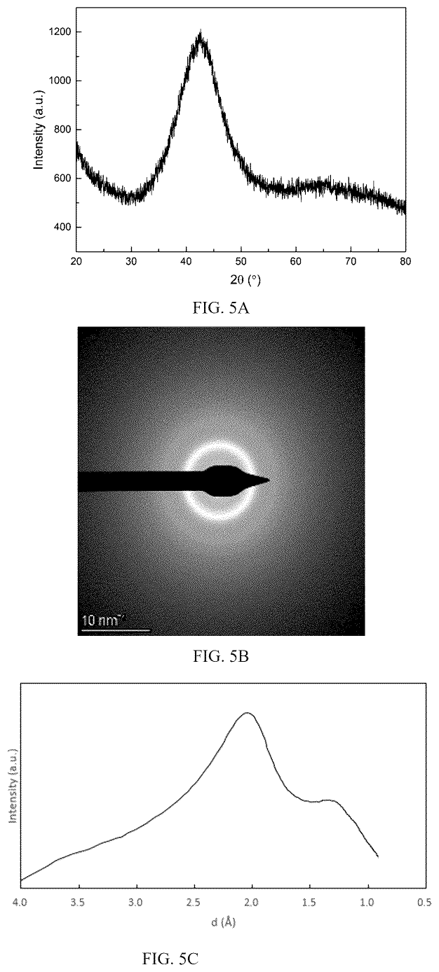

The test samples were characterized by SEM cross section, and the cross-sectional morphology can be seen in FIG. 4. The XRD pattern, the SAED pattern, and the radial intensity profile can be seen in FIG. 5. The SEM result showed that the Cr—Zr—N alloy coating had a dense structure, with no observable penetrating columnar gap. The XRD result showed that in the XRD pattern, there was a broad peak in the diffraction angle 2θ (°) range of 30° to 50°; and in the XRD pattern, 2θ (°) diffraction peak(s) in the range of 30° to 50° all had a full width at half maximum of ≥2°; among them, there was only one broad peak with a full width at half maximum of 9.11° in the range of 30° to 50°; and in the radial intensity profile of the TEM selected area electron diffraction pattern, there was only one broad peak with a full width at half maximum of 0.75 Å in the range of 2.0 Å to 3.0 Å.

### Example 2

In this Example, the chemical composition of the Cr—Zr—N alloy coating was Cr_{61.4}Zr_{33.2}N_{5.4}. The Cr—Zr—N alloy coating was prepared as follows.

In this Example, a chromium-zirconium alloy target was used as the target material. The original Cr target at the position of the Cr target 4 in FIG. 3 was replaced with a CrZr alloy target with a Cr:Zr atomic ratio of 65%:35%.

Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine. The vacuum chamber was evacuated to 5×10⁻⁴ Pa and maintained at room temperature (about 30 °C) for 15 min.

Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.

Deposition of the alloy coating: A rotating stand of the sample stage was turned on with the speed set to 6 rpm. The distance from the sample stage to the target surface was adjusted to 8 cm. The CrZr alloy target was electrified with a radio frequency assisted direct-current power supply. Ar gas and N₂ gas were introduced, with the N₂ gas flow rate set to 7 sccm and the Ar:N₂ gas volume ratio set to 6:1. The furnace pressure was maintained at 0.7 Pa. The bias voltage was initiated and set to −100 V. The power density of the CrZr alloy target was set to 5 W/cm². A Cr—Zr—N alloy coating was deposited, and the film formation time was controlled to obtain a resulting film thickness of 2500 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis, XRD analysis and TEM characterization.

The compositional analysis showed that the alloy coating on the surface of the substrate was composed of Cr_{61.4}Zr_{33.2}N_{5.4}.

The chroma value test results were L: 79.05, a: 0.43, b: 3.54 for the aluminum alloy substrate sample, and L: 81.74, a: 0.33, b: 3.04 for the stainless steel substrate sample. The samples showed a silvery white color.

In the corrosion resistance evaluation by salt spray test, the aluminum alloy substrate sample can pass the 48-h test, and the stainless steel substrate sample can pass the 144-h test, showing excellent protection properties.

The hardness values of the aluminum alloy substrate sample and the stainless steel substrate sample were tested to be 15.1 GPa and 16.3 GPa, respectively.

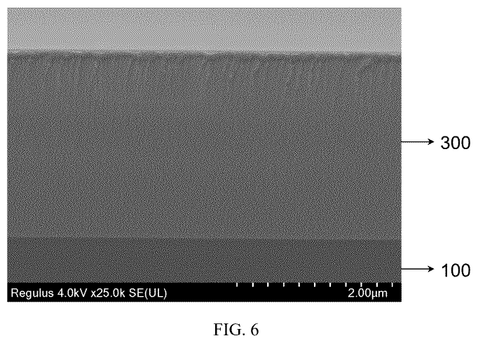

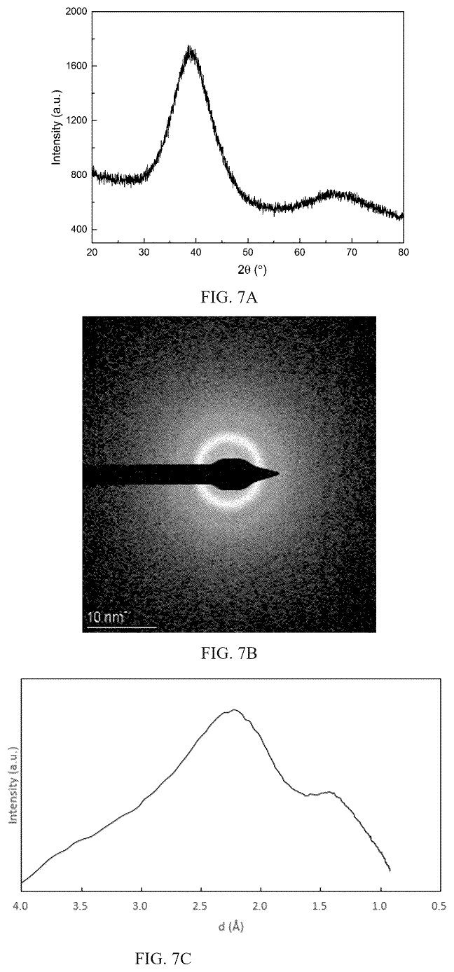

The samples were subjected to SEM cross section characterization, and the cross-sectional morphology can be seen in FIG. 6. The XRD pattern, the SAED pattern, and the radial intensity profile can be seen in FIG. 7. The SEM result showed that the Cr—Zr—N alloy coating has a dense structure, with no observable penetrating columnar gap. The XRD result showed that in the XRD pattern, 2θ (°) diffraction peak(s) in the range of 30° to 50° all had a full width at half maximum of ≥2°; among them, there was only one broad peak with a full width at half maximum of 8.85° in the range of 30° to 50°; and in the radial intensity profile of the TEM selected area electron diffraction pattern, there was only one broad peak with a full width at half maximum of 1.02 Å in the range of 2.0 Å to 3.0 Å.

### Example 3

In this example, the chemical composition of the Cr—Zr—N alloy coating was Cr_{47.1}Zr_{17.4}N_{35.5}. The Cr—Zr—N alloy coating was prepared as follows.

Pretreatment of substrate: Samples including a stainless steel sheet, an aluminum alloy sheet, and a silicon wafer each with a dimension of 50 mm×50 mm, were ultrasonically cleaned in deionized water for 15 min, dried in an oven, and placed in a vacuum chamber of a coating machine. The vacuum chamber was evacuated to 5×10⁻⁴ Pa, heated to 150 °C, and kept at a constant temperature for 15 min.

Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.

Deposition of the alloy coating: A rotating stand of the sample stage was turned on with the speed set to 6 rpm. The distance from the sample stage to the target surface was adjusted to 8 cm. Cr target and Zr target were electrified with a radio frequency assisted direct-current power supply. Ar gas and N₂ gas were introduced, with the N₂ gas flow rate set to 42 sccm and the Ar:N₂ gas volume ratio set to 2:1. The furnace pressure was maintained at 0.8 Pa. The bias voltage was initiated and set to −100 V. The power density of the Cr target was set to 3.9 W/cm², and the power density of the Zr target was set to 1.9 W/cm². A Cr—Zr—N alloy coating was deposited, and the film formation time was controlled to obtain a resulting film thickness of 1600 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis, XRD analysis and TEM characterization.

The compositional analysis showed that the alloy coating on the surface of the substrate was composed of Cr_{47.1}Zr_{17.4}N_{35.5}.

The chroma value test results were L: 73.92, a: 0.43, b: 4.78 for the aluminum alloy substrate sample, and L: 75.50, a: 0.36, b: 4.69 for the stainless steel substrate sample. The samples showed a brightly silvery white color.

In the corrosion resistance evaluation by salt spray test, the aluminum alloy substrate sample can pass the 48-h test, and the stainless steel substrate sample can pass the 144-h test, showing excellent protection properties.

The hardness values of the aluminum alloy substrate sample and the stainless steel substrate sample were tested to be 18.2 GPa and 20.4 GPa, respectively.

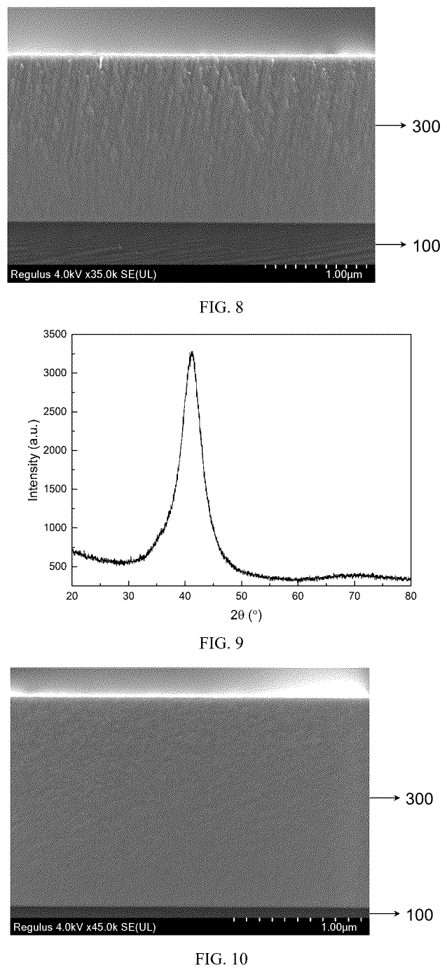

The samples were subjected to SEM cross-section characterization, and the cross-sectional morphology is shown in FIG. 8 and the XRD pattern is shown in FIG. 9. The SEM result showed that the Cr—Zr—N alloy coating had a dense structure, with no observable penetrating columnar gap. The XRD result showed that in the XRD pattern, there was a broad peak in the diffraction angle 2θ (°) range of 30° to 50°, and 2θ (°) peak(s) in the range of 30° to 50° all had a full width at half maximum value of ≥2°, among them, there was only one broad peak with a full width at half maximum of 4.42° in the range of 30° to 50°, and in the radial intensity profile of the TEM selected area electron diffraction pattern, there was only one broad peak with a full width at half maximum of 0.61 Å in the range of 2.0 Å to 3.0 Å.

### Example 4

In this example, the chemical composition of the Cr—Zr—N alloy coating was Cr_{52.0}Zr_{12.1}N_{35.9}. The Cr—Zr—N alloy coating was prepared as follows.

Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine. The vacuum chamber was evacuated to 5×10⁻⁴ Pa, heated to 150 °C, and kept at a constant temperature for 15 min.

Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.

Deposition of the alloy coating: A rotating stand of the sample stage was turned on with the speed set to 6 rpm. The distance from the sample stage to the target surface was adjusted to 8 cm. Cr target and Zr target were electrified with a radio frequency assisted direct-current power supply. Ar gas and N₂ gas were introduced, with the N₂ gas flow rate set to 42 sccm and the Ar:N₂ gas volume ratio set to 2:1. The furnace pressure was maintained at 0.8 Pa. The bias voltage was initiated and set to −100 V. The power density of the Cr target was set to 4.1 W/cm², and the power density of the Zr target was set to 1.5 W/cm². A Cr—Zr—N alloy coating was deposited, and the film formation time was controlled to obtain a resulting film thickness of 1700 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis, XRD analysis and TEM characterization.

The compositional analysis showed that the alloy coating on the surface of the substrate was composed of Cr_{52.0}Zr_{12.1}N_{35.9}.

The chroma value test results were L: 74.16, a: 0.47, b: 4.00 for the aluminum alloy substrate sample, and L: 75.70, a: 0.41, b: 3.95 for the stainless steel substrate sample. The samples showed a silvery white color.

In the corrosion resistance evaluation by salt spray test, the aluminum alloy substrate sample can pass the 48-h test, and the stainless steel substrate sample can pass the 144-h test, showing excellent protection properties.

The hardness values of the aluminum alloy substrate sample and the stainless steel substrate sample were tested to be 16.7 GPa and 19.2 GPa, respectively.

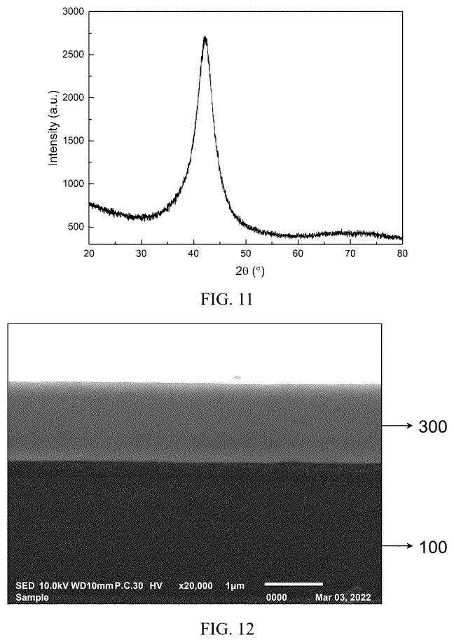

The samples were subjected to SEM cross-section characterization. The cross-sectional morphology is shown in FIG. 10 and the XRD pattern is shown in FIG. 11. The SEM result showed that the Cr—Zr—N alloy coating had a dense structure, with no observable penetrating columnar gap. The XRD result showed that in the XRD pattern, there was a broad peak in the diffraction angle 2θ (°) range of 30° to 50°, and 2θ (°) peak(s) in the range of 30° to 50° all had a full width at half maximum of ≥2°°; among them, there was only one broad peak with a full width at half maximum of 4.04° in the range of 30° to 50°; and in the radial intensity profile of the TEM selected area electron diffraction pattern, there was only one broad peak with a full width at half maximum of 0.42 Å in the range of 2.0 Å to 3.0 Å.

### Example 5

In this Example, the chemical composition of the Cr—Zr—N alloy coating was Cr_{60.9}Zr_{26.1}N_{13.0}. The Cr—Zr—N alloy coating was prepared as follows.

Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine. The vacuum chamber was evacuated to 5×10⁻⁴ Pa, heated to 150 °C, and kept at a constant temperature for 15 min.

Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.

Deposition of the alloy coating: A rotating stand of the sample stage was turned on with the speed set to 6 rpm. The distance from the sample stage to the target surface was adjusted to 8 cm. Cr target and Zr target were electrified with a radio frequency assisted direct-current power supply. Ar gas and N₂ gas were introduced, with the N₂ gas flow rate set to 14 sccm and the Ar:N₂ gas volume ratio set to 3:1. The furnace pressure was maintained at 0.7 Pa. The bias voltage was initiated and set to −100 V. The power density of the Cr target was set to 5 W/cm², and the power density of the Zr target was set to 2.7 W/cm². A Cr—Zr—N alloy coating was deposited, and the film formation time was controlled to obtain a resulting film thickness of 1000 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis, XRD analysis and TEM characterization.

The compositional analysis showed that the alloy coating on the surface of the substrate was composed of Cr_{60.9}Zr_{26.1}N_{13.0}.

The chroma value test results were L: 79.21, a: 0.41, b: 3.91 for the aluminum alloy substrate sample, and L: 79.95, a: 0.33, b: 3.73 for the stainless steel substrate sample. The samples showed a brightly silvery white color.

In the corrosion resistance evaluation by salt spray test, the aluminum alloy substrate sample can pass the 48-h test, and the stainless steel substrate sample can pass the 144-h test, showing excellent protection properties.

The hardness value was tested as 11.8 GPa for the aluminum alloy substrate sample and 13.7 GPa for the stainless steel substrate sample.

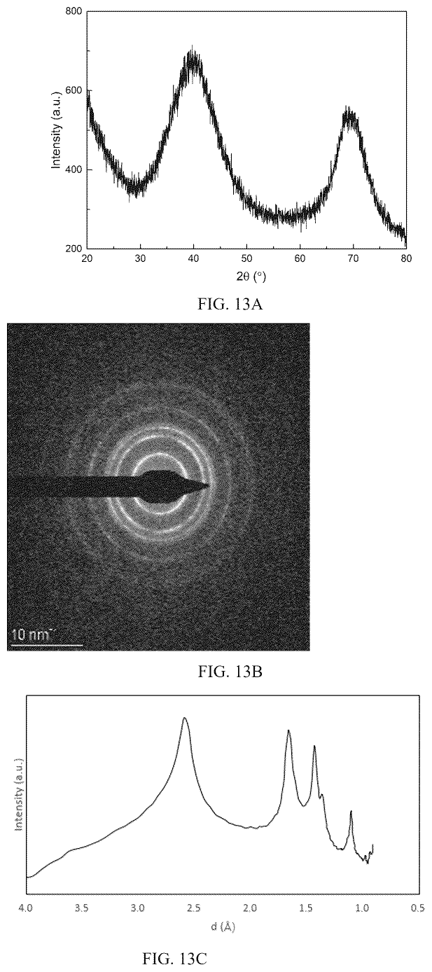

The samples to be tested were subjected to SEM cross section characterization, and the cross-sectional morphology can be seen in FIG. 12. The XRD pattern, the SAED pattern, and the radial intensity profile can be seen in FIG. 13. The SEM result showed that the Cr—Zr—N alloy coating had a dense structure, with no observable penetrating columnar gap. The XRD result showed that in the XRD pattern, there was a broad peak in the diffraction angle 2θ (°) range of 30° to 50°; and in the XRD pattern, the 2θ (°) peak(s) in the range of 30° to 50° all had a full width at half maximum value ≥2°; among them, there was only one broad peak with a full width at half maximum of 9.33° in the range of 30° to 50°; and in the radial intensity profile of the TEM selected area electron diffraction pattern, there was only one broad peak in the range of 2.0 Å to 3.0 Å, which had a full width at half maximum of 0.21 Å.

### Example 6

In this Example, a double-layer film structure was attached to the surface of the substrate. The double-layer film structure includes a Cr—Zr—N alloy coating with a chemical composition of Cr_{60.9}Zr_{26.1}N₁₃ and a second coating with a chemical composition of TiN. The double-layer film structure was recited as Cr—Zr—N/TiN. In this case, a multi-layer film structure was attached to the surface of the substrate, wherein the Cr—Zr—N alloy coating provided in the present application served as an intermediate layer, located between the substrate and the surface layer. The preparation method was as follows.

Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine. The vacuum chamber was evacuated to 5×10⁻⁴ Pa, heated to 150 °C, and kept at a constant temperature for 15 min.

Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.

Deposition of the alloy coating: A rotating stand of the sample stage was turned on with the speed set to 6 rpm. The distance from the sample stage to the target surface was adjusted to 8 cm. Cr target and Zr target were electrified with a radio frequency assisted direct-current power supply. Ar gas and N₂ gas were introduced, with the N₂ gas flow rate set to 14 sccm and the Ar:N₂ gas volume ratio set to 3:1. The furnace pressure was maintained at 0.7 Pa. The bias voltage was initiated and set to −100 V. The power density of the Cr target was set to 5 W/cm², and the power density of the Zr target was set to 2.7 W/cm². A Cr—Zr—N alloy coating was deposited, and the film formation time was controlled to obtain a resulting film thickness of 1000 nm.

Deposition of the surface layer (i.e., the second coating): the Zr target in the furnace was replaced with a Ti target. A rotating stand of the sample stage was turned on with the speed set to 6 rpm. The distance from the sample stage to the target surface was adjusted to 8 cm. The Ti target was electrified with a direct-current power supply. Ar gas and N₂ gas were introduced, with the N₂ gas flow rate set to 10 sccm and the Ar:N₂ gas volume ratio set to 3:1. The furnace pressure was maintained at 0.5 Pa. The bias voltage was initiated and set to −100 V. The power density of the Ti target was set to 5 W/cm2. A TiN coating was deposited, and the film formation time was controlled to obtain a resulting film thickness of 100 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis, XRD analysis and TEM characterization.

According to compositional analysis, the alloy coating with the composition of Cr_{60.9}Zr_{26.1}N₁₃ was coated with the TiN coating on its surface.

The chroma value test results, here which refer to the chroma values of the surface layer TiN, were L: 58.85, a: 6.65, b: 12.85 for the aluminum alloy substrate sample, and L: 59.83, a: 6.82, b: 13.61 for the stainless steel substrate sample. The samples showed a golden yellow color.

In the corrosion resistance evaluation by salt spray test, the aluminum alloy substrate sample can pass the 48-h test, and the stainless steel substrate sample can pass the 144-h test, showing excellent protection properties.

The hardness value was tested as 11.7 GPa for the aluminum alloy substrate sample and 14.2 GPa for the stainless steel substrate sample.

The test sample was subjected to SEM cross-section characterization, and the cross-sectional morphology is shown in FIG. 14. The SEM result showed that the Cr—Zr—N alloy coating has a dense structure,

It should be noted that the vertical cracks in the SEM morphology image of FIG. 14 are cracks generated in the process of breaking the silicon wafer but are not columnar gaps caused by the growth of the Cr—Zr—N film.

### Example 7

In this Example, a three-layer film structure was attached to the surface of the substrate. The three-layer film structure includes a transition layer (as a bottom coating), an alloy coating containing a Cr—Zr—N alloy material, and a second coating located on the surface stacked in sequence from the substrate surface. The three-layer film structure was recited as Cr/Cr—Zr—N/TIN, wherein the transition layer was a Cr layer, the chemical composition of the Cr—Zr—N alloy coating was Cr_{60.9}Zr_{26.1}N₁₃, and the chemical composition of the second coating was TIN. The preparation method was as follows.

Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine. The vacuum chamber was evacuated to 5×10⁻⁴ Pa, heated to 150 °C, and kept at a constant temperature for 15 min.

Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.

Deposition of the bottom coating (i.e., the transition layer): A rotating stand of the sample stage was turned on with the speed set to 6 rpm. The distance from the sample stage to the target surface was adjusted to 8 cm. Cr target was electrified with a radio frequency assisted direct-current power supply. Ar gas was introduced, with the Ar gas flow rate set to 42 sccm. The furnace pressure was maintained at 0.5 Pa. The bias voltage was initiated and set to −100 V. The power density of the Cr target was set to 5 W/cm². A Cr coating was deposited, and the film formation time was controlled to obtain a resulting film thickness of 300 nm.

Deposition of the Cr—Zr—N alloy coating of the present application: A rotating stand of the sample stage was turned on with the speed set to 6 rpm. The distance from the sample stage to the target surface was adjusted to 8 cm. Cr target and Zr target were electrified with a radio frequency assisted direct-current power supply. Ar gas and N₂ gas were introduced, with the N₂ gas flow rate set to 14 sccm and the Ar:N₂ gas volume ratio set to 3:1. The furnace pressure was maintained at 0.7 Pa. The bias voltage was initiated and set to −100 V. The power density of the Cr target was set to 5 W/cm², and the power density of the Zr target was set to 2.7 W/cm². A Cr—Zr—N alloy coating was deposited, and the film formation time was controlled to obtain a resulting film thickness of 1000 nm.

Deposition of the surface layer (i.e., the second coating): the Zr target in the furnace was replaced with a Ti target. A rotating stand of the sample stage was turned on with the speed set to 6 rpm. The distance from the sample stage to the target surface was adjusted to 8 cm. The Ti target was electrified with a direct-current power supply. Ar gas and N₂ gas were introduced, with the N₂ gas flow rate set to 10 sccm and the Ar:N₂ gas volume ratio set to 3:1. The furnace pressure was maintained at 0.5 Pa. The bias voltage was initiated and set to −100 V. The power density of the Ti target was set to 5 W/cm². A TiN coating was deposited, and the film formation time was controlled to obtain a resulting film thickness of 100 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis, XRD analysis and TEM characterization.

The compositional analysis showed that there was a three-layer film structure attached to the surface of the substrate, and the chemical composition was Cr (for the transition layer), Cr_{60.9}Zr_{26.1}N₁₃ (for the Cr—Zr—N alloy coating of the present application) and TIN (for the second coating). The three-layer film structure was Cr/Cr—Zr—N/TiN.

The chroma value test results, here which refer to chroma values of the surface layer TiN, were L: 56.64, a: 7.07, b: 14.11 for the aluminum alloy substrate sample, and L: 58.73, a: 7.35, b: 14.35 for the stainless steel substrate sample. The samples showed a golden yellow color.

In the corrosion resistance evaluation by salt spray test, the aluminum alloy substrate sample can pass the 48-h test, and the stainless steel substrate sample can pass the 144-h test, showing excellent protection properties.

The hardness value was tested as 13.2 GPa for the aluminum alloy substrate sample and 15.1 GPa for the stainless steel substrate sample.

The test sample was subjected to SEM cross-section characterization, and the cross-sectional morphology can be seen in FIG. 15. The SEM result showed that the alloy coating has a dense structure.

It should be noted that the vertical cracks in the SEM morphology image of FIG. 15 are cracks generated in the process of breaking the silicon wafer but are not columnar gaps caused by the growth of the Cr—Zr—N film.

### Example 8

In this Example, the chemical composition of the Cr—Zr—N alloy coating was Cr_{60.9}Zr_{26.1}N₁₃. The Cr—Zr—N alloy coating was prepared as follows.

Pretreatment of substrate: Samples including a copper sheet and a silicon wafer each with a dimension of 50 mm×50 mm were ultrasonically cleaned in deionized water for 15 min, dried in an oven, and placed in a vacuum chamber of a coating machine. The vacuum chamber was evacuated to 5×10⁻⁴ Pa, heated to 150 °C, and kept at a constant temperature for 15 min.

Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.

Deposition of the Cr—Zr—N alloy coating: A rotating stand of the sample stage was turned on with the speed set to 6 rpm. The distance from the sample stage to the target surface was adjusted to 8 cm. Cr target and Zr target were electrified with a radio frequency assisted direct-current power supply. Ar gas and N₂ gas were introduced, with the N₂ gas flow rate set to 14 sccm and the Ar:N₂ gas volume ratio set to 3:1. The furnace pressure was maintained at 0.7 Pa. The bias voltage was initiated and set to −100 V. The power density of the Cr target was set to 5 W/cm², and the power density of the Zr target was set to 2.7 W/cm². A Cr—Zr—N alloy coating was deposited, and the film formation time was controlled to obtain a resulting film thickness of 1000 nm.

The sample in which the copper sheet served as the substrate was subjected to corrosion resistance evaluation by salt spray test, hardness test, and chroma value test. The sample in which the silicon wafer served as the substrate was subjected to SEM characterization and compositional analysis, XRD analysis and TEM characterization.

The compositional analysis showed that the alloy coating on the surface of the substrate was composed of Cr_{60.9}Zr_{26.1}N_{13.}

The chroma value test result was L: 80.15, a: 0.53, b: 4.63 for the copper substrate sample. The copper substrate sample was a brightly silvery white color.

In the corrosion resistance evaluation by salt spray test, the copper substrate sample can pass the 12 h test and has certain protective properties.

The hardness value was tested as 7.9 GPa for the copper substrate sample.

The SEM result showed that the Cr—Zr—N alloy coating had a dense structure, with no observable penetrating columnar gap. The XRD result showed that in the XRD pattern, there was a broad peak; and 2θ (°) diffraction peak(s) in the range of 30° to 50° all had a full width at half maximum of ≥2°; among them, there was only one broad peak with a full width at half maximum of 9.33° in the range of 30° to 50°; and in the radial intensity profile of the TEM selected area electron diffraction pattern, there was only one broad peak in the range of 2.0 Å to 3.0 Å, which had a full width at half maximum of 0.21 Å.

### Example 9. Cr—Zr—N Alloy Coating Having Thickness of 50 nm

A Cr—Zr—N alloy coating whose chemical composition was Cr_{60.9}Zr_{26.1}N_{13.0} was prepared using a method substantially the same as that of Example 5, except that the thickness of the Cr—Zr—N alloy coating was adjusted to 50 nm.

The chroma value test results were L: 80.11, a: 0.41, b: 3.61 for the aluminum alloy substrate sample, and L: 80.95, a: 0.34, b: 3.43 for the stainless steel substrate sample. The samples showed a brightly silvery white color.

In the corrosion resistance evaluation by salt spray test, the aluminum alloy substrate sample can pass the 48-h test, and the stainless steel substrate sample can pass the 144-h test, showing excellent protection properties.

The hardness value was tested as 8.2 GPa for the aluminum alloy substrate sample and 9.7 GPa for the stainless steel substrate sample.

### Example 10. Cr—Zr—N Alloy Coating Having Thickness of 6 μm

A Cr—Zr—N alloy coating whose chemical composition was Cr_{60.9}Zr_{26.1}N_{13.0} was prepared using a method substantially the same as that of Example 5, except that the thickness of the Cr—Zr—N alloy coating was adjusted to 6000 nm.

The chroma value test results were L: 77.31, a: 0.45, b: 3.81 for the aluminum alloy substrate sample, and L: 76.94, a: 0.34, b: 3.83 for the stainless steel substrate sample. The samples showed a brightly silvery white color.

In the corrosion resistance evaluation by salt spray test, the aluminum alloy substrate sample can pass the 48-h test, and the stainless steel substrate sample can pass the 144-h test, showing excellent protection properties.

The hardness value was tested as 22.8 GPa for the aluminum alloy substrate sample and 24.7 GPa for the stainless steel substrate sample.

### Example 11. Containing Doping Elements

In this Example, the chemical composition of the Cr—Zr—N alloy coating containing doped elements was Cr_{47.1}Zr_{17.4}N_{30.5}C₅. In this case, the sum of the atomic ratios of Cr, Zr, and N was normalized to 100, thus the atomic ratio of Cr, Zr, and N was approximately 49.579:18.316:32.105. The atomic ratio of the doping element C in the Cr—Zr—N alloy coating was 5%. The preparation method was as follows:
Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine The vacuum chamber was evacuated to 5×10⁻⁴ Pa, heated to 150 °C, and kept at a constant temperature for 15 min.
Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.
Deposition of the Cr—Zr—N alloy coating of the present application: A rotating stand of the sample stage was turned on with the speed set to 6 rpm. The distance from the sample stage to the target surface was adjusted to 8 cm. Cr target and Zr target were electrified with a radio frequency assisted direct-current power supply. Ar gas, C₂H₂ gas and N₂ gas were introduced, with the N₂ gas flow rate set to 35 sccm, the C₂H₂ gas flow rate set to 6 sccm and the Ar:(C₂H₂+N₂) gas volume ratio set to 2:1. The furnace pressure was maintained at 0.8 Pa. The bias voltage was initiated and set to −100 V. The power density of the Cr target was set to 3.9 W/cm², and the power density of the Zr target was set to 1.9 W/cm². A Cr—Zr—N—C alloy coating of the present application which was a carbon-doped Cr—Zr—N alloy coating was deposited, and the film formation time was controlled to obtain a resulting film thickness of 1600 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis, XRD analysis and TEM characterization.

The compositional analysis showed that the alloy coating on the surface of the substrate was composed of Cr_{47.1}Zr_{17.4}N_{30.5}C₅.

The chroma value test results were L: 72.72, a: 0.41, b: 4.58 for the aluminum alloy substrate sample, and L: 73.81, a: 0.38, b: 4.27 for the stainless steel substrate sample. The samples showed a brightly silvery white color. In the XRD pattern, there was at least one broad peak in the range of a diffraction angle 20 (°) of 30°to 50°, and in the radial intensity profile of a TEM selected-area electron diffraction pattern, there was at least one broad peak in the range of 2.0 Å to 3.0 Å.

In the corrosion resistance evaluation by salt spray test, the aluminum alloy substrate sample can pass the 48-h test, and the stainless steel substrate sample can pass the 144-h test, showing excellent protection properties.

The hardness value was tested as 18.9 GPa for the aluminum alloy substrate sample and 20.4 GPa for the stainless steel substrate sample.

According to the experimental exploration results from the inventors, when other non-metallic doping elements (such as Si, B, O, etc.) or metal doping elements (such as Al) were used, high brightness and excellent corrosion resistance can also be obtained as long as the atomic ratio of the doping element was appropriate (such as 4 at %, 2 at %). In some of the embodiments, in the corrosion resistance evaluation by salt spray test, the aluminum alloy substrate sample can pass the 48-h test, and the stainless steel substrate sample can pass the 144-h test. In the XRD pattern, there may be at least one broad peak in the diffraction angle 2θ (°) range of 30° to 50°; and in the radial intensity profile of the TEM selected-area electron diffraction pattern, there was at least one broad peak in the range of 2.0 Å to 3.0 Å. In addition, the Cr—Zr—N alloy coating also has relatively high hardness.

“At %” refers to atomic ratio.

### Example 12

In this Example, the chemical composition of the alloy coating was Cr₅₀Zr₃₀N₂₀. The element composition did not satisfy the following formula combination: 63.19−0.925y≤x≤95.79−y and 31.4+0.9y≤x≤18.5y−171.85.

In this Example, the chemical composition of the alloy coating was Cr₅₀Zr₃₀N₂₀. The preparation method was as follows.
Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine The vacuum chamber was evacuated to 5×10⁻⁴ Pa, heated to 150 °C, and kept at a constant temperature for 15 min.
Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.

Deposition of the alloy coating: A rotating stand of the sample stage was turned on with the speed set to 6 rpm. The distance from the sample stage to the target surface was adjusted to 8 cm. Cr target and the Zr target were electrified with a radio frequency assisted direct-current power supply. Ar gas and N₂ gas were introduced, with the N₂ gas flow rate set to 18 sccm and the Ar:N₂ gas volume ratio set to 3:1. The furnace pressure was maintained at 0.7 Pa. The bias voltage was initiated and set to −100 V. The power density of the Cr target was set to 4.5 W/cm², and the power density of the Zr target was set to 3.0 W/cm². A Cr—Zr—N alloy coating was deposited, and the film formation time was controlled to obtain a resulting film thickness of 1000 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis, XRD analysis and TEM characterization.

The compositional analysis showed that the alloy coating on the surface of the substrate was composed of Cr₅₀Zn₃₀N₂₀.

The chroma value test results were L: 77.01, a: 0.92, b: 4.52 for the aluminum alloy substrate sample, and L: 79.06, a: 0.54, b: 3.98 for the stainless steel substrate sample. The samples showed a brightly silvery white color. In the corrosion resistance evaluation by salt spray test, the aluminum alloy substrate sample can pass the 24-h test (but did not pass the 48-h test), and the stainless steel substrate sample can pass the 96-h test (but did not pass the 144-h test), showing excellent protection properties. The hardness value was tested as 11.6 GPa for the aluminum alloy substrate sample and 12.7 GPa for the stainless steel substrate sample.

In the XRD pattern, there was at least one broad peak in the diffraction angle 2θ (°) range of 30° to 50°. In the radial intensity profile of the TEM selected-area electron diffraction pattern, there was at least one broad peak in the range of 2.0 Å to 3.0 Å.

### Example 13

In this Example, the chemical composition of the alloy coating was Cr_{49.5}Zr_{18.0}N_{32.5}. The preparation method was as follows.
Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine The vacuum chamber was evacuated to 5×10⁻⁴ Pa, heated to 150 °C, and kept at a constant temperature for 15 min.
Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.
Deposition of the alloy coating: A rotating stand of the sample stage was turned on with the speed set to 6 rpm. The distance from the sample stage to the target surface was adjusted to 8 cm. Cr target and Zr target were electrified with a radio frequency assisted direct-current power supply. Ar gas and N₂ gas were introduced, with the N₂ gas flow rate set to 42 sccm and the Ar:N₂ gas volume ratio set to 2:1. The furnace pressure was maintained at 0.8 Pa. The bias voltage was initiated and set to −100 V. The power density of the Cr target was set to 4.7 W/cm², and the power density of the Zr target was set to 1.8 W/cm². A Cr—Zr—N alloy coating was deposited, and the film formation time was controlled to obtain a resulting film thickness of 1600 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was used in XRD analysis and TEM characterization.

The compositional analysis showed that the alloy coating on the surface of the substrate was composed of Cr_{49.5}Zr_{18.0}N_{32.5}.

The chroma value test results were L: 74.52, a: 0.41, b: 4.48 for the aluminum alloy substrate sample, and L: 75.70, a: 0.32, b: 4.39 for the stainless steel substrate sample. The samples showed a brightly silvery white color.

In the corrosion resistance evaluation by salt spray test, the aluminum alloy substrate sample can pass the 48-h test, and the stainless steel substrate sample can pass the 144-h test, showing excellent protection properties.

The hardness value was tested as 18.5 GPa for the aluminum alloy substrate sample and 19.4 GPa for the stainless steel substrate sample.

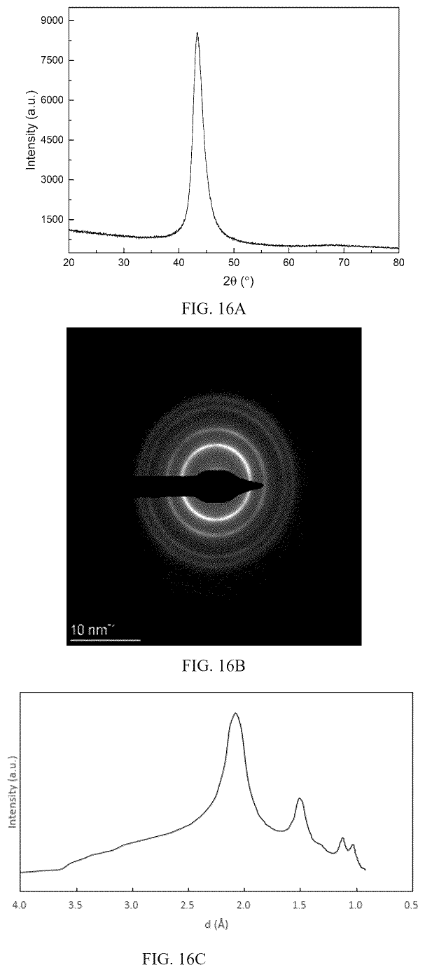

The XRD results (referring to (A) in FIG. 16) showed that in the XRD pattern, there was a broad peak in the diffraction angle 2θ (°) range of 30° to 50°, and in the XRD pattern, the 2θ (°) peak(s) in the range of 30° to 50° all had a full width at half maximum value ≥2°; among them, there was only one broad peak with a full width at half maximum of 2.19° in the range of 30° to 50°. The SAED test result (referring to (B) and (C) in FIG. 16) showed that in the radial intensity profile (C) corresponding to the TEM selected area electron diffraction pattern (B), there was only one broad peak in the range of 2.0 Å to 3.0 Å, which had a full width at half maximum of 0.27 Å.

Regarding analysis of the intrinsic mechanism for high hardness and excellent corrosion resistance of the Cr—Zr—N alloy coating provided in the present application, the inventors of the present application have discovered through a large number of experimental explorations that, the prepared Cr—Zr—N alloy coating had both excellent corrosion resistance and high hardness when the present Cr—Zr—N alloy coating satisfies the following two conditions: (1) in the XRD pattern, there was at least one broad peak in the diffraction angle 2θ (°) range of 30° to 50°, and (2) in the radial intensity profile of the TEM selected-area electron diffraction pattern, there was at least one broad peak in the range of 2.0 Å to 3.0 Å. If there was at least one broad peak in the diffraction angle 2θ (°) range of 30° to 50° in the XRD pattern, but there was no broad peak in the range of 2.0 Å to 3.0 Å in the radial intensity profile of the SAED pattern, the prepared Cr—Zr—N alloy coating may have poor corrosion resistance, and for example, the corresponding aluminum alloy substrate sample thereof may not pass the 24-h corrosion resistance evaluation by salt spray test. If there was at least one broad peak in the range of 2.0 Å to 3.0 Å in the radial intensity profile of the SAED pattern, but there was no broad peak in the diffraction angle 2θ (°) range of 30° to 50° in the XRD pattern, the Cr—Zr—N alloy coating may exhibit poor corrosion resistance. Reference can be made to Comparative Example 4 below.

### Comparative Example 1

In this comparative example, the chemical composition of the alloy coating was Cr_{88.9}Zr_{11.1}. The preparation method was as follows.
Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine The vacuum chamber was evacuated to 5×10⁻⁴ Pa, heated to 150°C, and kept at a constant temperature for 15 min.
Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.
Deposition of Cr—Zr alloy coating: A rotating stand of the sample stage was turned on with the speed set to 6 rpm. The distance from the sample stage to the target surface was adjusted to 8 cm. Cr target and Zr target were electrified with a radio frequency assisted direct-current power supply. Ar gas was introduced. The furnace pressure was maintained at 0.6 Pa. The bias voltage was initiated and set to −100 V. The power density of the Cr target was set to 6.7 W/cm², and the power density of the Zr target was set to 0.8 W/cm². A Cr—Zr alloy coating was deposited, and the film formation time was controlled to obtain a resulting film thickness of 1900 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis test.

The compositional analysis showed that the alloy coating on the surface of the substrate was composed of Cr_{88.9}Zr_{11.1}.

The chroma value test results were L: 83.21, a: −0.21, b: 0.88 for the aluminum alloy substrate sample, and L: 85.05, a: −0.25, b: 0.79 for the stainless steel substrate sample. The samples showed a silvery white color.

The sample was subjected to SEM cross-section characterization, and the cross-sectional morphology can be seen in FIG. 17. The SEM result showed that the alloy coating film had crystal defects, a loose structure, and obvious gaps.

In the corrosion resistance evaluation by salt spray test, the aluminum alloy substrate sample failed the 48-h test (i.e., NG, with a protection time of <24 h), and the stainless steel substrate sample failed the 144-h test (i.e., NG, with a protection time of <48 h), showing poor protection properties.

The hardness value was tested as 18.5 GPa for the aluminum alloy substrate sample and 19.6 GPa for the stainless steel substrate sample.

### Comparative Example 2

In this comparative example, the chemical composition of the alloy coating was Cr_{37.8}Zr_{16.2}N₄₆. The preparation method was as follows.
Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine The vacuum chamber was evacuated to 5×10⁻⁴ Pa, heated to 150 °C, and kept at a constant temperature for 15 min.
Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.
Deposition of the alloy coating: A rotating stand of the sample stage was turned on with the speed set to 6 rpm. The distance from the sample stage to the target surface was adjusted to 8 cm. Cr target and Zr target were electrified with a radio frequency assisted direct-current power supply. Ar gas and N₂ gas were introduced, with the N₂ gas flow rate set to 52 sccm and the Ar:N₂ gas volume ratio set to 2:1. The furnace pressure was maintained at 0.9 Pa. The bias voltage was initiated and set to −100 V. The power density of the Cr target was set to 3.5 W/cm², and the power density of the Zr target was set to 1.8 W/cm². A Cr—Zr—N alloy coating was deposited, and the film formation time was controlled to obtain a resulting film thickness of 1000 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis, XRD analysis and TEM characterization.

The compositional analysis showed that the alloy coating on the surface of the substrate was composed of Cr_{37.8}Zr_{16.2}N₄₆.

The chroma value test results were L: 61.87, a: 0.57, b: 4.45 for the aluminum alloy substrate sample, and L: 67.38, a: 0.49, b: 4.29 for the stainless steel substrate sample. The samples showed a dull color and no metallic color.

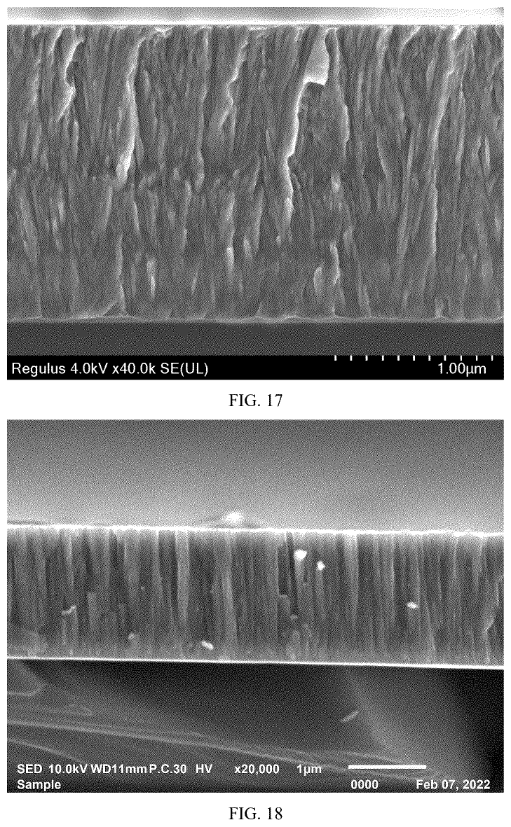

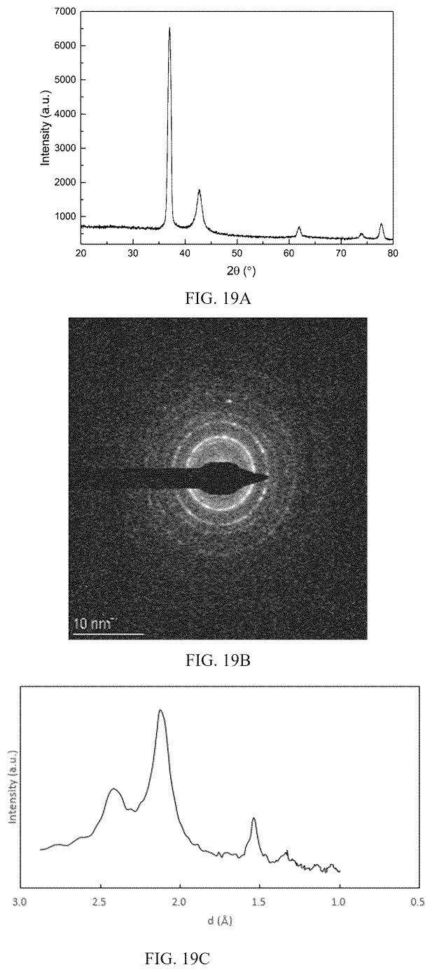

The samples were subjected to SEM cross-section characterization, and the cross-sectional morphology can be seen in FIG. 18. The test results of XRD pattern, TEM selected area electron diffraction pattern and radial intensity profile can be seen in FIG. 19. The SEM result showed that the alloy coating film has a loose structure, with obvious penetrating columnar gaps. The XRD result showed that in the XRD pattern, there were two peaks in the diffraction angle 2θ (°) range of 30° to 50°, which were both sharp peaks (i.e., 2θ peaks with full width at half maximum value of <2°). Among them, the full width at half maximum values of the two peaks in the range of 30° to 50° were 0.66° and 1.24°, respectively. In the radial intensity profile of the TEM selected-area electron diffraction pattern, there were two peaks in the range of 2.0 Å to 3.0 Å, with full width at half maximum values of 0.13 Å and 0.18 Å, respectively; that is, there were two sharp peaks.

In the corrosion resistance evaluation by salt spray test, the aluminum alloy substrate sample failed the 48-h test (i.e., NG, with a protection time of <24 h), and the stainless steel substrate sample failed the 144-h test (i.e., NG, with a protection time of <48 h), showing poor protection properties.

The hardness value was tested as 16.6 GPa for the aluminum alloy substrate sample and 18.1 GPa for the stainless steel substrate sample.

### Comparative Example 3

In this comparative example, the structure of the film was TIN, and the chemical composition of the alloy coating was TIN.

To prepare the alloy coating in the comparative example, the Zr target in the furnace was replaced with a Ti target, and the preparation method was as follows.
Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine The vacuum chamber was evacuated to 5×10⁻⁴ Pa, heated to 150 °C, and kept at a constant temperature for 15 min.
Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.
Deposition of the TiN coating: A rotating stand of the sample stage was turned on with the speed set to 6 rpm. The distance from the sample stage to the target surface was adjusted to 8 cm. The Ti target was electrified with a direct-current power supply. Ar gas and N₂ gas were introduced, with the N₂ gas flow rate set to 10 sccm and the Ar:N₂ gas volume ratio set to 3:1. The furnace pressure was maintained at 0.5 Pa. The bias voltage was initiated and set to −100 V. The power density of the Ti target was set to 5 W/cm². A TiN coating was deposited, and the film formation time was controlled to obtain a resulting film thickness of 200 nm.

The samples in which the stainless steel sheet and the aluminum alloy sheet respectively served as the substrate were subjected to corrosion resistance evaluation by salt spray test, hardness test, and chroma value test.

The compositional analysis showed that the alloy coating on the surface of the substrate was composed of TiN.

The chroma value test results were L: 57.95, a: 6.45, b: 13.95 for the aluminum alloy substrate sample, and L: 59.33, a: 6.92, b: 13.91 for the stainless steel substrate sample. The samples showed a golden yellow color.

In the corrosion resistance evaluation by salt spray test, the aluminum alloy substrate sample failed the 48-h test (i.e., NG, with a protection time of <12 h), and the stainless steel substrate sample failed the 144-h test (i.e., NG, with a protection time of <24 h).

The hardness value was tested as 3.8 GPa for the aluminum alloy substrate sample and 4.3 GPa for the stainless steel substrate sample.

### Comparative Example 4

In this comparative example, the chemical composition of the alloy coating was Cr_{39.6}Zr_{19.4}N₄₁, and the preparation method was as follows.
Pretreatment of substrate: Samples including a stainless steel sheet, an aluminum alloy sheet, and a silicon wafer each with a dimension of 50 mm×50 mm were ultrasonically cleaned in deionized water for 15 min, dried in an oven, and placed in a vacuum chamber of a coating machine The vacuum chamber was evacuated to 5×10⁻⁴ Pa, heated to 150 °C, and kept at a constant temperature for 15 min.
Plasma cleaning: Ar gas was introduced, a furnace pressure was maintained at 2.0 Pa, a bias voltage was initiated and set to −800 V, and then plasma cleaning was performed for 20 min, for the purpose of removing tiny impurities on the sample surface using plasma etching.
Deposition of the alloy coating: A rotating stand of the sample stage was turned on with the speed set to 6 rpm. The distance from the sample stage to the target surface was adjusted to 8 cm. Cr target and Zr target were electrified with a radio frequency assisted direct-current power supply. Ar gas and N₂ gas were introduced, with the N₂ gas flow rate set to 45 sccm and the Ar:N₂ gas volume ratio set to 2:1. The furnace pressure was maintained at 0.8 Pa. The bias voltage was initiated and set to −100 V. The power density of the Cr target was set to 4.6 W/cm², and the power density of the Zr target was set to 2.2 W/cm². A Cr—Zr—N alloy coating was deposited, and the film formation time was controlled to obtain a resulting alloy coating film of thickness of 1400 nm.

The samples in which the stainless steel sheet and the aluminum alloy sheet respectively served as the substrate were subjected to corrosion resistance evaluation by salt spray test, hardness test, and chroma value test. The sample in which the silicon wafer served as the substrate was subjected to SEM characterization and compositional analysis, XRD analysis and TEM characterization.

The compositional analysis showed that the alloy coating on the surface of the substrate was composed of Cr_{39.6}Zr_{19.4}N₄₁.

The chroma value test results were L: 64.71, a: 0.58, b: 4.15 for the aluminum alloy substrate sample, and L: 66.38, a: 0.49, b: 4.27 for the stainless steel substrate sample. The samples showed a silvery white color.

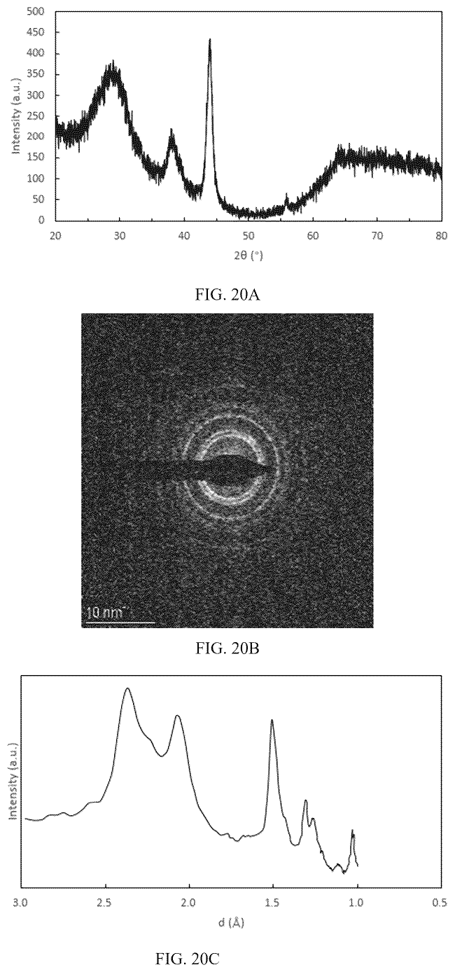

The SEM result showed that the alloy coating film had crystal defects, a loose structure, and obvious penetrating columnar gaps. The test results of the XRD pattern, TEM selected area electron diffraction pattern and radial intensity profile can be seen in FIG. 20. The XRD result showed that in the XRD pattern, there were two peaks in the diffraction angle 2θ (°) range of 30° to 50°, which were both sharp peaks (i.e., 2θ peaks with full width at half maximum value of <2°). Among them, the full width at half maximum values of the two peaks in the range of 30° to 50° were 1.87° and 1.02°, respectively. In the radial intensity profile of the TEM selected-area electron diffraction pattern, there were two peaks in the range of 2.0 Å to 3.0 Å, with full width at half maximum values of 0.18 Å and 0.21 Å, respectively, that is, there was one sharp peak.

In the corrosion resistance evaluation by salt spray test, the aluminum alloy substrate sample failed the 48-h test (i.e., NG, with a protection time of <12h), and the stainless steel substrate sample failed the 144-h test (i.e., NG, with a protection time of <24 h), showed no protective properties for the substrate.

The hardness value was tested as 15.4 GPa for the aluminum alloy substrate sample and 17.2 GPa for the stainless steel substrate sample.

### Comparative Example 5. Alloy Coating Having Thickness of 50 nm

An alloy coating whose chemical composition was Cr_{39.6}Zr_{19.4}N₄₁ was prepared using a method substantially the same as that of Comparative Example 4, except that the thickness of the alloy coating was different, changed from 1400 nm to 50 nm.

In the corrosion resistance evaluation by salt spray test, the aluminum alloy substrate sample failed the 48-h test (i.e., NG, with a protection time of <12 h), and the stainless steel substrate sample failed the 144-h test (i.e., NG, with a protection time of <24 h), showed no protective properties for the substrate. The hardness value was tested as 9.1 GPa for the aluminum alloy substrate sample and 9.8 GPa for the stainless steel substrate sample.

### Comparative Example 6. Alloy Coating Having Thickness of 1000 nm

An alloy coating whose chemical composition was Cr_{39.6}Zr_{19.4}N₄₁ was prepared using a method substantially the same as that of Comparative Example 4, except that the thickness of the alloy coating was different, changed from 1400 nm to 1000 nm.

In the corrosion resistance evaluation by salt spray test, the aluminum alloy substrate sample failed the 48-h test (i.e., NG, with a protection time of <12 h), and the stainless steel substrate sample failed the 144-h test (i.e., NG, with a protection time of <24 h), showed no protective properties for the substrate. The hardness value was tested as 16.5 GPa for the aluminum alloy substrate sample and 17.9 GPa for the stainless steel substrate sample.

### Comparative Example 7. Alloy Coating Having Thickness of 2500 nm

An alloy coating whose chemical composition was Cr_{39.6}Zr_{19.4}N₄₁ was prepared using a method substantially the same as that of Comparative Example 4, except that the thickness of the alloy coating was different, changed from 1400 nm to 2500 nm.

In the corrosion resistance evaluation by salt spray test, the aluminum alloy substrate sample failed the 48-h test (i.e., NG, with a protection time of <12 h), and the stainless steel substrate sample failed the 144-h test (i.e., NG, with a protection time of <24 h), showed no protective properties for the substrate. The hardness value was tested as 20.5 GPa for the aluminum alloy substrate sample and 21.1 GPa for the stainless steel substrate sample.

### Comparative Example 8. Alloy Coating Having Thickness of 6000 nm

An alloy coating whose chemical composition was Cr_{39.6}Zr_{19.4}N₄₁ was prepared using a method substantially the same as that of Comparative Example 4, except that the thickness of the alloy coating was different, changed from 1400 nm to 6000 nm.

In the corrosion resistance evaluation by salt spray test, the aluminum alloy substrate sample failed the 48-h test (i.e., NG, with a protection time of <12 h), and the stainless steel substrate sample failed the 144-h test (i.e., NG, with a protection time of <24 h), showed no protective properties for the substrate. The hardness value was tested as 22.1 GPa for the aluminum alloy substrate sample and 23.7 Gpa for the stainless steel substrate sample.

### Comparative Examples 9-11. No Protective Coating

An aluminum alloy bare sheet, a stainless steel bare sheet and a copper bare sheet were respectively subjected to corrosion resistance evaluation by salt spray test. The results showed that obvious corrosion occurred within 12 hours.

### Result Analysis

Cr, Zr, and N elements in the Cr—Zr—N alloy coating provided in the present application were in a certain atomic ratio, and the content of Cr was high.

The protective coatings in Examples 1-5 and 8-13 were single-layer film structures. The Cr—Zr—N alloy coatings provided in the present application directly provided surface protection for the substrates. In these cases, the surfaces of the alloy film products had relatively high brightness value. Moreover, the results of corrosion resistance evaluation by salt spray test showed that the Cr—Zr—N alloy coatings provided in Examples 1-13 can be used as the protective coating itself or as part of the protective coating, both of which can bring excellent corrosion resistance to the substrate.

The results of corrosion resistance evaluation by salt spray test showed that the Cr—Zr—N alloy coatings of Examples 1-13 provided in the present application can bring excellent corrosion resistance to the substrate. Example 6 provided a double-layer film structure, in which the Cr—Zr—N alloy coating provided in the present application served as a lower protective layer, and a surface layer (TiN) was further attached to the surface of the Cr—Zr—N alloy coating on the side away from the substrate and served as a protective surface coating (i.e., an upper layer). The Cr—Zr—N alloy coating of Example 7 was a three-layer film structure, including a transition layer as a bottom coating, a Cr—Zr—N alloy coating, and a TiN coating on the top stacked in sequence from the substrate surface. The Cr—Zr—N alloy coating in Example 11 contained a certain atomic ratio of doping elements (≤5 at %).

In Examples 1-7, 9-11, and 13, an aluminum alloy substrate and a stainless steel substrate were used. The aluminum alloy surface can pass the 48-h corrosion resistance evaluation by salt spray test, and the stainless steel surface can pass the 144-h corrosion resistance evaluation by salt spray test. In Example 8, a copper substrate was used, and the copper (which is a more active alloy) substrate can pass the 12-h corrosion resistance evaluation by salt spray test.

In Example 12, the element composition of the Cr—Zr—N alloy coating did not meet the following formula combination: 63.19−0.925y≤x≤95.79−y and 31.4+0.9y≤x≤18.5y−171.85. The aluminum alloy surface can pass the 24-h corrosion resistance evaluation by salt spray test (but did not pass the 48-h test), and the stainless steel surface can pass the 96-h corrosion resistance evaluation by salt spray test (but did not pass the 144-h test).

The alloy coating provided in the present application can be independently used as a single-layer film. Alternatively, the alloy coating provided in the present application can be arranged in a multi-layer composite film, for example, as one layer of the multiple layers, that is, as an exposed surface layer, or as a bottom coating in contact with the substrate, or as an intermediate layer between the bottom coating and the surface layer.

The results of XRD test and TEM selected area electron diffraction test showed that, for the Cr—Zr—N alloy coatings of Examples 1-13 provided in the present application, there was at least one broad peak in the diffraction angle 2θ (°) range of 30° to 50° in the XRD pattern, and further, all were broad peaks with full width at half maximum of ≥2°; and there was at least one broad peak in the range of 2.0 Å to 3.0 Å in the radial intensity profile of the TEM selected area electron diffraction pattern, and further, all were broad peaks with full width at half maximum of ≥0.21 Å. The Cr—Zr—N alloy coatings in all of the Examples had a highly disordered and sufficiently densely packed atomic arrangement, which was consistent with the highly dense structure in the SEM morphology characterization results.

In addition, the Cr—Zr—N alloy coatings of Examples 1-13 provided in the present application also had relatively high hardness, and thus they had both excellent corrosion resistance and high hardness.

The substrate bare sheets of Comparative Examples 9-11, without a protective coating, were not resistant to salt spray corrosion and suffered obvious corrosion within 12 hours.

The alloy coating film of Comparative Example 1 lacked the N element, the alloy coating films of Comparative Example 2 and Comparative Example 4 had a high content of N element, and Comparative Example 3 was not provided with the Cr—Zr—N alloy coating (a TiN coating in Comparative Example 3). It was found that Comparative Examples 1-4 all failed (NG) in the corrosion resistance test. The inventor speculated that the reason may be that the film structure was not dense and had gaps such as penetrating columnar gaps, such that the corrosive solution can quickly pass through the gaps and be in contact with the substrate, resulting in failure of the coating corrosion resistance.

For the alloy coatings with different thicknesses in Comparative Examples 5-8, their hardness and corrosion resistance were significantly inferior to those of the Cr—Zr—N alloy coating with the same thickness in the present application. Among them, Comparative Example 8, even though having a thickness up to 6000 nm (6 microns), exhibited still poor corrosion resistance. The possible reason was speculated to be that the film structure was not dense and had gaps such as penetrating columnar gaps, such that the corrosive solution can quickly pass through the gaps and be in contact with the substrate, resulting in failure of the coating corrosion resistance. Although increasing the thickness of the coating can increase the hardness of the coating, structural defects still exist. However, the Cr—Zr—N alloy coating provided in the present application can have both excellent corrosion resistance and high hardness at a relatively low thickness, thereby saving raw materials, simplifying the process, shortening the production cycle, and significantly reducing costs. When the alloy coating is thin, the formed alloy film product can present a silvery white metallic color, which is close to the metallic color of the substrate, thereby being conducive to achieving a beautiful decorative effect without changing the color of the substrate.

The technical features of the above-mentioned embodiments and examples can be combined in any appropriate way. In order to make the description concise, not all possible combinations of the technical features are described in the embodiments and examples. However, as long as there is no contradiction in the combination of these technical features, the combinations should be considered as in the scope of the present application.

The above-described embodiments and examples are only several implementations of the present application to facilitate a detailed understanding of the technical solution of the present application, but they should not be construed as limiting the scope of the present application. It should be understood by those of ordinary skill in the art that various modifications and improvements can be made without departing from the concept of the present application, and all fall within the protection scope of the present application. In addition, it should be understood that, after reading the above teaching of the present application, those skilled in the art can make various changes or modifications to the present application, and the obtained equivalent forms also fall within the scope of protection of the present application. It should also be understood that the technical solutions obtained by those skilled in the art through logical analysis, reasoning or limited experiments on the basis of the technical solutions provided in the present application are within the scope of the appended claims of the present application. Therefore, the patent protection of the present application shall be defined by the appended claims, and the specification and drawings can be used to explain the contents of the claims.

1-19. (canceled)

20. A Cr—Zr—N alloy material, wherein the Cr—Zr—N alloy material is represented by a chemical formula of (CrₓZr_{y}N_{z})Mₐ, where M is a doping element, wherein x, y, z and a are each independently atomic ratios, 47.1≤x≤81.6, 12.1≥y≤33.2, 4.7≥z≥35.9, and 0≤a/(x+y+z+a)≤0.05.

21. The Cr—Zr—N alloy material according to claim 20, wherein a sum of x, y, and z is 100.

22. The Cr—Zr—N alloy material according to claim 20, wherein y is greater than z.

23. The Cr—Zr—N alloy material according to claim 20, wherein 63.19−0.925y≤x≤95.79−y, and 31.4+0.9y≤x≤18.5y−171.85.

24. The Cr—Zr—N alloy material according to claim 20, wherein the doping element is a non-metallic element, a metallic element, or a combination thereof;
the non-metallic element comprises one or more of O, C, B, Si, and Ar; and
the metallic element comprises one or more of Ti, V, Nb, Mo, Hf, Ta, W, Ni, Mo, Fe, Ag, Au, Cu, and Al.

25. The Cr—Zr—N alloy material according to claim 20, wherein 0≤a/(x+y+z+a)≤0.02.

26. A Cr—Zr—N alloy coating, wherein the Cr—Zr—N alloy coating comprises a film layer formed with the Cr—Zr—N alloy material according to claim 20.

27. The Cr—Zr—N alloy coating according to claim 26, wherein the Cr—Zr—N alloy material or the Cr—Zr—N alloy coating satisfies the following two characteristics:
in an X-ray diffraction (XRD) pattern of the Cr—Zr—N alloy material or the Cr—Zr—N alloy coating, there is a peak in a diffraction angle 2θ (°) range of 30° to 50°, and at least one 2θ (°) diffraction peak in the range of 30° to 50° has a full width at half maximum (FWHM) of ≥2°; and
in a radial intensity profile corresponding to a selected area electron diffraction (SAED) pattern of the Cr—Zr—N alloy coating, with a characteristic interatomic spacing as a horizontal axis and a diffraction intensity as a vertical axis, there is a diffraction peak in a range of 2.0 Å to 3.0 Å, and at least one diffraction peak in the range of 2.0 Å to 3.0 Å has an FWHM of ≥0.21 Å.

28. The Cr—Zr—N alloy coating according to claim 26, wherein the Cr—Zr—N alloy coating satisfies one or more of the following characteristics:
the XRD pattern of the Cr—Zr—N alloy coating is obtained by Cu target Kα radiation; and
the SAED pattern of the Cr—Zr—N alloy coating is obtained by using a transmission electron microscope, with an electron acceleration voltage of 200 kV and a selected area diaphragm diameter of 900 nm.

29. The Cr—Zr—N alloy coating according to claim 26, wherein the Cr—Zr—N alloy coating has a thickness of dₘᵢₙ to 6 μm, wherein dₘᵢₙ is selected from 10 nm to 50 nm;
optionally, dₘᵢₙ is 10 nm, 20 nm, 25 nm, 30 nm, 40 nm, or 50 nm;
optionally, a thickness of the Cr—Zr—N alloy coating is 1 μm to 2.5 μm.

30. An alloy film product, comprising a substrate and the Cr—Zr—N alloy coating according to claim 26; wherein the Cr—Zr—N alloy coating is disposed on at least one side of the substrate.

31. The alloy film product according to claim 30, wherein a surface material of the substrate is one of an alloy, an elemental metal, or a non-metallic inorganic material;
optionally, the alloy comprises one or more material types selected from nickel-based, iron-based, tungsten-based, titanium-based, silicon-based, aluminum-based, copper-based, cobalt-based, zirconium-based, and zinc-based materials;
optionally, the elemental metal is any one of zinc, gold, platinum, zirconium, hafnium, niobium, tantalum, nickel, copper, aluminum, iron, silver, and chromium;
optionally, the non-metallic inorganic material comprises one or both of ceramics and glass.

32. The alloy film product according to claim 30, wherein the surface material of the substrate is one of light alloys or one of stainless steels;
optionally, the light alloy comprises one or more of a titanium alloy, an aluminum alloy, and a magnesium alloy.

33. The alloy film product according to claim 30, wherein the alloy film product satisfies one or more of the following characteristics:
the Cr—Zr—N alloy coating and the substrate are in direct contact with each other, or a transition layer is provided between the alloy coating and the substrate;
the Cr—Zr—N alloy coating is disposed on a surface of the alloy film product; or a surface layer is provided on one side of the Cr—Zr—N alloy coating away from the substrate and the surface layer is a single-layer structure or a multi-layer structure.

34. The alloy film product according to claim 30, wherein the alloy film product is one of a 3C digital product, an automotive product, an aerospace product, a wearable product, and a sport product.

35. A high-brightness surface coating, wherein the Cr—Zr—N alloy material according to claim 20 is used to prepare the high-brightness surface coating, wherein the high-brightness surface coating has a brightness value L of ≥70 as determined by Lab method, and the high-brightness surface coating is a corrosion-resistant protective coating.

36. A method for preparing a Cr—Zr—N alloy coating, comprising the following step:
depositing constituent elements of the Cr—Zr—N alloy coating in a predetermined atomic ratio on at least a portion of a surface of a substrate through vapor deposition technique to form the Cr—Zr—N alloy coating according to claim 26.

37. The method according to claim 36, wherein the method for preparing the Cr—Zr—N alloy coating comprises the following step: sputter deposition of constituent elements of the Cr—Zr—N alloy coating on at least a portion of the surface of the substrate by using one or more target materials including chromium and zirconium under introducing a mixed gas including argon gas and nitrogen-containing gas to form the Cr—Zr—N alloy coating.

38. The method according to claim 37, wherein the method satisfies one or more of the following characteristics:
the sputter deposition is performed at a temperature of 30 °C to 330 °C;
the mixed gas comprising argon gas and nitrogen-containing gas has a total gas pressure of 0.3 Pa to 1.2 Pa;
the target materials comprise a chromium target and a zirconium target, a power density of the chromium target is 3.5 W/cm² to 6.7 W/cm², and a power density of the zirconium target is 0.5 W/cm² to 3.0 W/cm²;
the target materials comprise an alloy target comprising at least two metallic elements in the Cr—Zr—N alloy coating; optionally, the target materials comprise a chromium-zirconium-based alloy target which has a power density of 4 W/cm² to 6 W/cm²;
a bias voltage of the substrate is −150 V to −20 V;
the sputter deposition is performed for 10 min to 150 min;
the nitrogen-containing gas is nitrogen gas, and a gas flow rate of the nitrogen gas is 5 sccm to 52 sccm; and
the nitrogen-containing gas is nitrogen gas, and a gas volume ratio of argon gas to nitrogen gas in the mixed gas is 2:1 to 6:1.
